(19) United States
(12) Patent Application Publication
(10) Pub. No.: US 2024/0341140 A1
(43) Pub. Date: Oct. 10, 2024

(54) DISPLAY PANEL AND MANUFACTURING METHOD THEREFOR, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Haotian YANG, Beijing (CN); Xiangdong WEI, Beijing (CN); Miao LUO, Beijing (CN); Jiaming SHEN, Beijing (CN); Seungyong OH, Beijing (CN); Xiaoliang FU, Beijing (CN); Xiaoxia LIU, Beijing (CN); Kang WANG, Beijing (CN); Zheng BAO, Beijing (CN)

(21) Appl. No.: 18/579,368

(22) PCT Filed: Sep. 22, 2022
(86) PCT No.: PCT/CN2022/120496

§ 371 Date: Jan. 15, 2024

(30) Foreign Application Priority Data
Oct. 26, 2021 (CN) 202111250497.9

(51) Int. Cl. H10K 59/131; H10K 59/12; H10K 102/00

(52) U.S. Cl. CPC H10K 59/131; H10K 59/1201; H10K 2102/311

(57) ABSTRACT

The present disclosure provides a display panel and a manufacturing method therefor, and the display device. The display panel comprises a display area and a binding area, the binding area comprises a bending area and a composite circuit area which are sequentially arranged in a direction away from the display area, and the bending area is configured to turn the composite circuit area to the back of the display area by bending; a first functional hole is formed in the display area, a second functional hole is formed in the binding area, and the orthographic projection of the first functional hole on the plane of the display area at least partially overlaps the orthographic projection of the second functional hole on the plane of the display area.

### CROSS-REFERENCE TO RELATED APPLICATIONS

The present application is a U.S. National Phase Entry of International Application No. PCT/CN2022/120496 having an international filing date of Sep. 22, 2022, which claims priority to Application No. 202111250497.9 filed to the CNIPA on Oct. 26, 2021. The above-identified applications are hereby incorporated by reference in their entireties.

### TECHNICAL FIELD

The present disclosure relates, but is not limited, to the technical field of display, and particularly to a display panel, a preparation method thereof, and a display device.

### BACKGROUND

An Organic Light Emitting Diode (OLED for short) is an active light emitting display device, which has advantages of auto-luminescence, a wide viewing angle, a high contrast ratio, low power consumption, an extremely high response speed, lightness and thinness, bendability, and a low cost, etc. With continuous development of display technologies, a flexible display apparatus (Flexible Display) using an OLED as a light emitting device and performing signal control by use of a Thin Film Transistor (TFT for short) has become a mainstream product in the field of display at present, and has been widely used in mobile phones, computers, televisions, vehicles, smart wearable devices and other fields.

### SUMMARY

The following is a summary of subject matter described herein in detail. The summary is not intended to limit the protection scope of claims.

In one aspect, an exemplary embodiment of the present disclosure provides a display panel including a display region and a bonding region located on a side of the display region in a first direction. The bonding region includes a bending region and a composite circuit region arranged sequentially in a direction away from the display region, the bending region is configured to flip the composite circuit region to a back of the display region by being bent; the display region is provided with a first functional hole, and the bonding region is provided with a second functional hole. An orthographic projection of the first functional hole on a plane of the display region at least partially overlaps an orthographic projection of the second functional hole on the plane of the display region.

In an exemplary implementation, the orthographic projection of the first functional hole on the plane of the display region is within a range of the orthographic projection of the second functional hole on the plane of the display region.

In an exemplary implementation, an area of the orthographic projection of the first functional hole on the plane of the display region is 70% to 90% of an area of the orthographic projection of the second functional hole on the plane of the display region.

In an exemplary implementation, in a direction away from the first functional hole, a distance between an edge of the orthographic projection of the first functional hole on the plane of the display region and an edge of the orthographic projection of the second functional hole on the plane of the display region is 0.2 mm to 0.4 mm.

In an exemplary implementation, the display panel has a center line extending along the first direction, the center line bisects the display panel in a second direction, the orthographic projection of the first functional hole on the plane of the display region at least partially overlaps an orthographic projection of the center line on the plane of the display region, the orthographic projection of the second functional hole on the plane of the display region at least partially overlaps the orthographic projection of the center line on the plane of the display region, and the second direction intersects the first direction.

In an exemplary implementation, the display region includes a fixed display region and a rollable display region connected to each other, the bonding region is located on a side of the fixed display region in the first direction, the rollable display region is located on a side of the fixed display region in an opposite direction of the first direction, the first functional hole is located on the fixed display region, and the second functional hole is located on the composite circuit region in the bonding region.

In an exemplary implementation, on a plane perpendicular to the display region, a display panel in an overlapping region between the display region and the bonding region includes: a display substrate, a display structural layer disposed on the display substrate, a reinforcement structural layer disposed on a side of the display substrate away from the display structural layer, a bonding substrate disposed on a side of the reinforcement structural layer away from the display substrate, a bonding structural layer disposed on a side of the bonding substrate away from the display substrate, and; the first functional hole is a via penetrating through the display substrate and the display structural layer, the second functional hole is a via penetrating through the bonding substrate and the bonding structural layer, the reinforcement structural layer is provided with a first structural hole penetrating through the reinforcement structural layer, and the first structural hole is communicated with the first functional hole and the second functional hole.

In an exemplary implementation, the reinforcement structural layer includes: a first adhesive layer disposed on a side of the display substrate away from the display structural layer, a first reinforcement layer disposed on a side of the first adhesive layer away from the display substrate, a second adhesive layer disposed on a side of the first reinforcement layer away from the display substrate, a second reinforcement layer disposed on a side of the second adhesive layer away from the display substrate, and a bending spacer layer disposed on a side of the second reinforcement layer away from the display substrate, the bonding substrate is attached to a side of the bending spacer layer away from the display substrate.

In an exemplary implementation, the first adhesive layer is provided with a first adhesive hole, and the orthographic projection of the first functional hole on the plane of the display region is within a range of an orthographic projection of the first adhesive hole on the plane of the display region; in a direction away from the first functional hole, a distance between an edge of the orthographic projection of the first functional hole on the plane of the display region and an edge of the orthographic projection of the first adhesive hole on the plane of the display region is 0.2 mm to 0.8 mm.

In an exemplary implementation, the first reinforcement layer is provided with a first reinforcement hole, and the orthographic projection of the first functional hole on the plane of the display region is within a range of an orthographic projection of the first reinforcement hole on the plane of the display region; in a direction away from the first functional hole, a distance between an edge of the orthographic projection of the first functional hole on the plane of the display region and an edge of the orthographic projection of the first reinforcement hole on the plane of the display region is 0.2 mm to 0.5 mm.

In an exemplary implementation, a distance between an edge of the orthographic projection of the first functional hole on the plane of the display region and an edge of the orthographic projection of the first reinforcement hole on the plane of the display region is greater than a distance between the edge of the orthographic projection of the first functional hole on the plane of the display region and an edge of the orthographic projection of the second functional hole on the plane of the display region.

In an exemplary implementation, a distance between an edge of the orthographic projection of the first functional hole on the plane of the display region and an edge of the orthographic projection of the first adhesive hole on the plane of the display region is greater than a distance between the edge of the orthographic projection of the first functional hole on the plane of the display region and an edge of the orthographic projection of the first reinforcement hole on the plane of the display region.

In an exemplary implementation, the second adhesive layer is provided with a second adhesive hole, and the orthographic projection of the first functional hole on the plane of the display region is within a range of an orthographic projection of the second adhesive hole on the plane of the display region; in a direction away from the first functional hole, a distance between an edge of the orthographic projection of the first functional hole on the plane of the display region and an edge of the orthographic projection of the second adhesive hole on the plane of the display region is 0.2 mm to 0.5 mm.

In an exemplary implementation, the second reinforcement layer is provided with a second reinforcement hole, and the orthographic projection of the first functional hole on the plane of the display region is within a range of an orthographic projection of the second reinforcement hole on the plane of the display region; in a direction away from the first functional hole, a distance between an edge of the orthographic projection of the first functional hole on the plane of the display region and an edge of the orthographic projection of the second reinforcement hole on the plane of the display region is 0.2 mm to 0.5 mm.

In an exemplary implementation, a distance between an edge of the orthographic projection of the first functional hole on the plane of the display region and an edge of the orthographic projection of the first reinforcement hole on the plane of the display region is equal to a distance between the edge of the orthographic projection of the first functional hole on the plane of the display region and an edge of the orthographic projection of the second reinforcement hole on the plane of the display region.

In an exemplary implementation, the bending spacer layer is provided with a bending spacer hole, and the orthographic projection of the first functional hole on the plane of the display region is within a range of an orthographic projection of the bending spacer hole on the plane of the display region; in a direction away from the first functional hole, a distance between an edge of the orthographic projection of the first functional hole on the plane of the display region and an edge of the orthographic projection of the bending spacer hole on the plane of the display region is 0.2 mm to 0.8 mm.

In an exemplary implementation, the bonding region is further provided with a third functional hole, the third functional hole is a via penetrating through the bonding substrate and the bonding structural layer, and the reinforcement structural layer is further provided with a second structural hole, the second structural hole is a via penetrating through the reinforcement structural layer, the second structural hole is communicated with the third functional hole, and an orthographic projection of the third functional hole on the plane of the display region at least partially overlaps the orthographic projection of the second structural hole on the plane of the display region.

In an exemplary implementation, the bonding region is further provided with a virtual functional hole, the virtual functional hole has a same shape as the third functional hole, the virtual functional hole has a same size as the third functional hole, and the virtual functional hole and the third functional hole are symmetrically arranged relative to the second functional hole.

In another aspect, an exemplary embodiment of the present disclosure also provides a display device including the above-described display panel.

In yet another aspect, an exemplary embodiment of the present disclosure provides a preparation method of a display panel, the display panel includes a display region and a bonding region located on a side of the display region in a first direction, the bonding region includes a bending region and a composite circuit region arranged sequentially in a direction away from the display region; the preparation method includes: forming a first functional hole in the display region and forming a second functional hole in the bonding region; flipping the composite circuit region to a back of the display region by bending the bending region, wherein an orthographic projection of the first functional hole on the plane of the display region at least partially overlaps an orthographic projection of the second functional hole on the plane of the display region.

Other aspects may be understood upon reading and understanding of the drawings and detailed description.

### BRIEF DESCRIPTION OF DRAWINGS

Accompanying drawings are used for providing further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of various components in the drawings do not reflect actual scales, but are only intended to schematically illustrate contents of the present disclosure.

FIG. 1 is a schematic diagram of a structure of a display device.

FIG. 2 is a schematic diagram of a planar structure of a display panel in an unfolded state according to an exemplary embodiment of the present disclosure.

FIG. 3 is a side view of the display panel in FIG. 2 in a bent state.

FIG. 4 is a schematic diagram of a planar structure of a display region.

FIG. 5 is a schematic diagram of a sectional structure of a display region.

FIG. 6 is a schematic diagram of an equivalent circuit of a pixel drive circuit.

FIG. 7 is a working timing diagram of a pixel drive circuit.

FIG. 8 is a schematic diagram of a planar structure of a display panel in a bent state according to an exemplary embodiment of the present disclosure.

FIG. 9 is a sectional view taken along C-C in FIG. 8.

FIG. 10 is a schematic diagram of a display region after a pattern of a first functional hole is formed according to an embodiment of the present disclosure.

FIG. 11 is a schematic diagram of a bonding region after a pattern of a second functional hole is formed according to an embodiment of the present disclosure.

FIG. 12 is a schematic diagram after a cover plate is affixed according to an exemplary embodiment of the present disclosure.

FIG. 13 is a schematic diagram after a first reinforcement layer is attached according to an exemplary embodiment of the present disclosure.

FIG. 14 is a schematic diagram after a second reinforcement layer is attached according to an exemplary embodiment of the present disclosure.

FIG. 15 is a schematic diagram after a bending spacer layer is formed according to an exemplary embodiment of the present disclosure.

FIG. 16 is a schematic diagram of a planar structure of another display panel in an unfolded state according to an embodiment of the present disclosure.

FIG. 17 is a schematic diagram of a planar structure of the display panel in FIG. 16 in a bent state.

FIG. 18 is a sectional view taken along D-D in FIG. 17.

FIG. 19 is a schematic diagram of a planar structure of yet another display panel in an unfolded state according to an embodiment of the present disclosure.

Reference signs are described as follows.

| | | |
|---|---|---|
| 10-display structural layer; | 20-bonding structural layer; | 30-reinforcement structural |
| | | layer; |
| 31-first adhesive layer; | 32-first reinforcement layer; | 33-second adhesive layer; |
| 34-second reinforcement | 35-bending spacer layer; | 40-cover plate layer; |
| layer; | | |
| 41-cover plate adhesive layer; | 42-functional layer; | 43-plastic cover plate; |
| 44-protection layer; | 100-display region; | 101-substrate; |
| 102-drive structural layer; | 103-light emitting structural | 104-encapsulation structural |
| | layer; | layer; |
| 110-fixed display region; | 120- rollable display region; | 200-bonding region; |
| 210-lead region; | 220-bending region; | 230-composite circuit region; |
| 240-integrated circuit; | 250-flexible printed circuit | 300-first functional hole; |
| | board; | |
| 400-second functional hole; | 500-first structural hole; | 600-third functional hole; |
| 700-second structural hole; | 800-virtual functional hole. | |

### DETAILED DESCRIPTION

To make objectives, technical solutions, and advantages of the present disclosure clearer, embodiments of the present disclosure will be described in detail with reference to the accompanying drawings. It is to be noted that implementations may be implemented in a plurality of different forms. Those of ordinary skills in the art may easily understand such a fact that modes and contents may be transformed into various forms without departing from the purpose and scope of the present disclosure. Therefore, the present disclosure should not be explained as being limited to contents described in following implementations only. The embodiments in the present disclosure and features in the embodiments may be combined randomly with each other if there is no conflict. In order to keep following description of the embodiments of the present disclosure clear and concise, detailed description of part of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display panel and a quantity of sub-pixels in each pixel are not limited to numbers shown in the drawings. The drawings described in the present disclosure are structural schematic diagrams only, and one mode of the present disclosure is not limited to shapes, numerical values, or the like shown in the drawings.

Ordinal numerals such as “first”, “second”, and “third” in the specification are set to avoid confusion between constituent elements, but not to set a limit in quantity.

In the specification, for convenience, wordings indicating orientation or positional relationships, such as “middle”, “upper”, “lower”, “front”, “back”, “vertical”, “horizontal”, “top”, “bottom”, “inside”, and “outside”, are used for illustrating positional relationships between constituent elements with reference to the drawings, and are merely for facilitating the description of the specification and simplifying the description, rather than indicating or implying that a referred device or element must have a particular orientation and be constructed and operated in the particular orientation. Therefore, they cannot be understood as limitations on the present disclosure. The positional relationships between the constituent elements are changed as appropriate according to directions for describing various constituent elements. Therefore, appropriate replacements may be made according to situations without being limited to the wordings described in the specification.

In the specification, unless otherwise specified and defined explicitly, terms “mount”, “mutually connect”, and “connect” should be understood in a broad sense. For example, a connection may be a fixed connection, or a detachable connection, or an integrated connection; it may be a mechanical connection or an electrical connection; and it may be a direct mutual connection, or an indirect connection through middleware, or an internal communication between two elements. Those of ordinary skills in the art may understand specific meanings of these terms in the present disclosure according to specific situations.

In the specification, a transistor refers to an element which at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that, in the specification, the channel region refers to a region through which the current mainly flows.

In the specification, a first electrode may be a drain electrode, and a second electrode may be a source electrode; or, the first electrode may be a source electrode, and the second electrode may be a drain electrode. In cases that transistors with opposite polarities are used, a current direction changes during operation of a circuit, or the like, functions of the “source electrode” and the “drain electrode” are sometimes interchanged. Therefore, the “source electrode” and the “drain electrode” are interchangeable in the specification.

In the specification, an “electrical connection” includes a case that constituent elements are connected together through an element with a certain electrical effect. The “element with a certain electrical effect” is not particularly limited as long as electrical signals may be sent and received between the connected constituent elements. Examples of the “element with a certain electrical effect” not only include an electrode and a wiring, but also include a switching element such as a transistor, a resistor, an inductor, a capacitor, and another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulating film” may be replaced with an “insulating layer” sometimes.

Triangle, rectangle, trapezoid, pentagon, hexagon, etc. in this specification are not strictly defined, and they may be approximate triangle, rectangle, trapezoid, pentagon, hexagon, etc.

There may be some small deformations caused by tolerance, and there may be chamfer, arc edge, deformation, etc. In the present disclosure, “about” refers to that a boundary is not defined so strictly and numerical values within process and measurement error ranges are allowed.

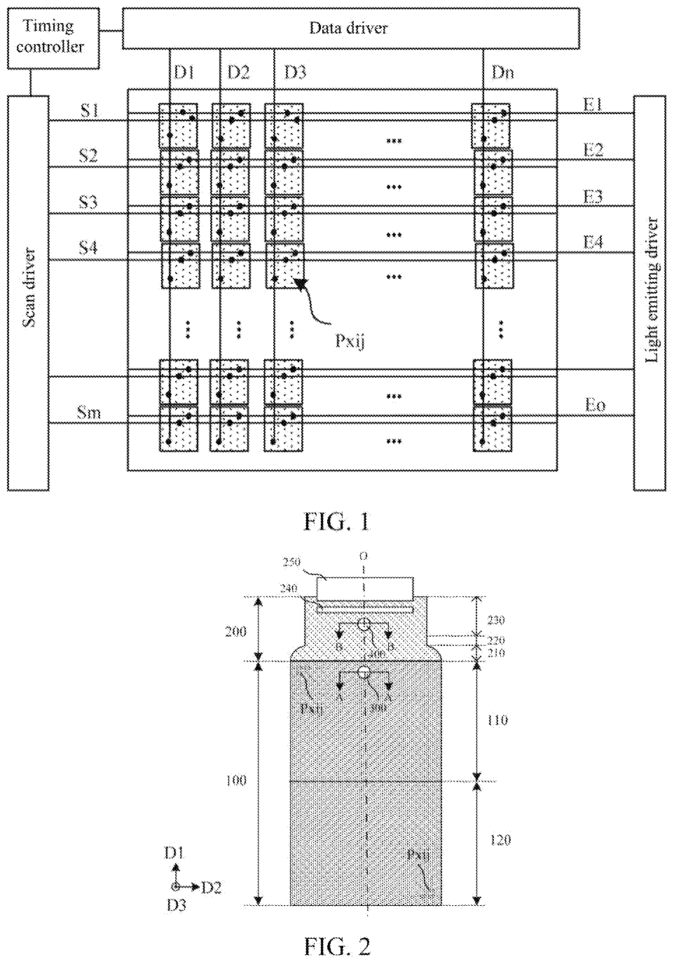

FIG. 1 is a schematic diagram of a structure of a display device. As shown in FIG. 1, the display device may include a timing controller, a data driver, a scan driver, a light emitting driver, and a pixel array. The timing controller is connected with the data driver, the scan driver, and the light emitting driver, respectively, the data driver is connected with a plurality of data signal lines (D1 to Dn) respectively, the scan driver is connected with a plurality of scan signal lines (S1 to Sm) respectively, and the light emitting driver is connected with a plurality of light emitting signal lines (E1 to Eo) respectively. The pixel array may include a plurality of sub-pixels Pxij, wherein i and j may be natural numbers, at least one sub-pixel Pxij may include a circuit unit and a light emitting device connected with the circuit unit, and the circuit unit may include at least one scan signal line, at least one data signal line, at least one light emitting signal line, and a pixel drive circuit. In an exemplary implementation, the timing controller may provide a grayscale value and a control signal suitable for the specification of the data signal driver to the data signal driver, may provide a clock signal, a scan start signal, etc. suitable for the specification of the scan driver to the scan driver, and may provide a clock signal, an emission stop signal, etc. suitable for the specification of the light emitting driver to the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a row of pixels as a unit, wherein n may be a natural number. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and generate a scan signal in a manner of sequentially transmitting a scan start signal provided in a form of an on-level pulse to a next-stage circuit under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number.

For a product such as an intelligent terminal, hardware such as a front camera, a fingerprint recognition sensor and an infrared sensor usually needs to be arranged. The existing traditional display devices usually provide functional holes in the display region, and arrange the hardware such as a front camera, a fingerprint recognition sensor and an infrared sensor in the functional holes. With continuous development of display technologies, many new flexible display devices have appeared in the market, such as rollable display devices and foldable display devices, etc. The display area of the rollable display device can be adjusted, which has the characteristics of convenient in usage, space saving and the like. In a rollable display device, a rollable display region capable of curling is provided above an upper side of a fixed display region, so that the functional hole is provided in the rollable display region. Through research, it is found that providing functional holes in the rollable display region not only increases the layout difficulty and structural complexity, but also causes poor display in the rollable display region due to the influence of stress concentration in the rollable display region.

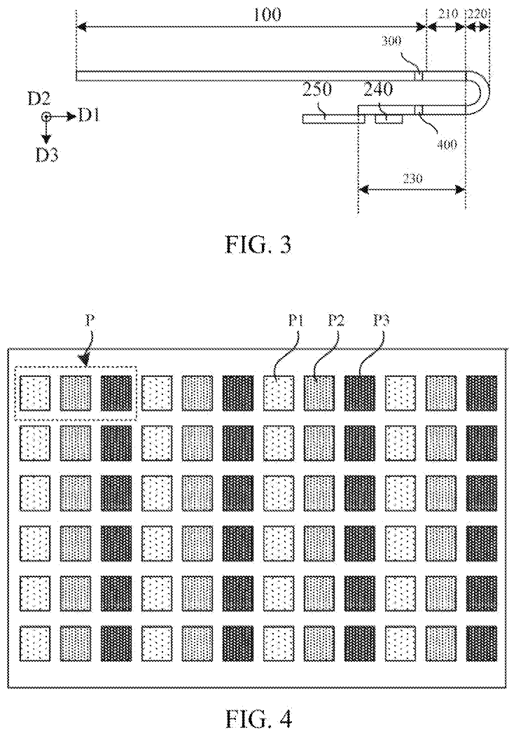

FIG. 2 is a schematic diagram of a planar structure of a display panel in an unfolded state according to an exemplary embodiment of the present disclosure, illustrating a state before the bonding region is bent, and FIG. 3 is a side view of the display panel in FIG. 2, illustrating a bent state after the bonding region is bent. As shown in FIGS. 2 and 3, on a plane parallel to the display panel, the display panel may include at least a display region 100 and a bonding region 200, and the bonding region 200 may be located on a side of the display region 100 in a first direction D1.

In an exemplary implementation, the display region 100 may include a plurality of sub-pixels Pxij that constitute an array of pixels, the plurality of sub-pixels Pxij are configured to perform image display, and the display region 100 may be deformable, for example, may be crimped, bent, folded, or curled. The bonding region 200 may include a bonding circuit configured to connect a signal line of the display region 100 to an external drive device. In an exemplary implementation, the bonding region 200 may be bent and attached to the back of the display region 100 in a bending manner, and the bonding region 200 may overlap the display region 100 in a direction perpendicular to the plane of the display region (a third direction D3).

In an exemplary implementation, the display region 100 may include a fixed display region 110 and a rollable display region 120 connected to each other. In an exemplary implementation, the fixed display region 110 is always in a planar state for image display and the rollable display region 120 is configured to achieve a contracted state and an extended state under the control of a telescoping mechanism. In the contracted state, the rollable display region 120 is bent and attached to the side and back of the telescoping mechanism and does not participate in the display. In the extended state, the rollable display region 120 is extended into a plane, and the fixed display region 110 and the rollable display region 120 together perform image display. Free adjustment of the display area in the display device is realized by the contracted state and the extended state of the rollable display region 120.

In an exemplary implementation, the bonding region 200 may be located on a side of the fixed display region 110 in the first direction D1, and the rollable display region 120 may be located on a side of the fixed display region 110 in an opposite direction of the first direction D1. In an exemplary implementation, according to user habits and appearance requirements, when the display device is in a normal use state, the rollable display region 120 is located on a lower side of the fixed display region 110, and the bonding region 200 is located on an upper side of the fixed display region 110.

In an exemplary implementation, the bonding region 200 may include a lead region 210, a bending region 220, and a composite circuit region 230 that are arranged in sequence along the first direction D1 (a direction away from the display region). The lead region 210 may be connected to the display region 100, the bending region 220 may be connected to the lead region 210, and the composite circuit region 230 may be connected to the bending region 220.

In an exemplary implementation, the lead region 210 may be provided with a plurality of fanout lines, one end of each of the plurality of fanout lines is correspondingly connected to a data signal line of a plurality of data signal lines in the display region 100, and the other end is connected to an integrated circuit of the composite circuit region 230, so that the integrated circuit may apply data signals to the plurality of data signal lines in the display region through the plurality of fanout lines.

In an exemplary implementation, the bending region 220 may be bent with a curvature in the third direction D3, so that a surface of the composite circuit region 230 may be flipped, that is, a surface, facing upwards, of the composite circuit region 230 may be flipped to be the face downwards by the bending of the bending region 220, where the third direction D3 intersects with the first direction D1. In an exemplary implementation, when the bending region 220 is bent, the composite circuit region 230 may be overlapped with the display region 100 in the third direction D3 (a thickness direction).

In an exemplary implementation, the composite circuit region 230 may include an electrostatic prevention region, a drive chip region, and a bonding pin region. An Integrated Circuit (IC) 240 may be bonded to the drive chip region, and a Flexible Printed Circuit (FPC) 250 may be bonded to the bonding pin region. In an exemplary implementation, the integrated circuit 240 may generate a drive signal required for driving sub-pixels, and may provide the drive signal to the sub-pixels in the display region 100. For example, the drive signal may be a data signal that drives luminance of the sub-pixel. In an exemplary implementation, the integrated circuit 240 may be bonded to the driver chip region by an anisotropic conductive film or other ways. A width of the integrated circuit 240 in a second direction D2 may be less than a width of the composite circuit region 230 in the second direction D2, where the second direction D2 is intersected with the first direction D1. In an exemplary implementation, the bonding pin region may include a plurality of pins (PIN) to which the flexible circuit board 250 may be bonded and connected.

In an exemplary implementation, the first direction D1 may be an extension direction (a column direction) of the data signal lines in the display region, the second direction D2 may be an extension direction (a row direction) of the scan signal lines in the display region, the third direction D3 may be a direction perpendicular to the plane of the display panel (a thickness direction), the first direction D1 and the second direction D2 may be perpendicular to each other, and the first direction D1 and the third direction D3 may be perpendicular to each other.

In an exemplary implementation, at least one first functional hole 300 may be provided near an edge of a side of the fixed display region 110 close to the bonding region 200, and at least one second functional hole 400 may be provided in the composite circuit region 230 of the bonding region 200. After the composite circuit region 230 is flipped to the back of the display region by the bending of the bending region 220, the first functional hole 300 and the second functional hole 400 are both located in an overlapping region where the display region and the bonding region overlap, and a position of the first functional hole 300 corresponds to a position of the second functional hole 400, so that an optical device may be disposed in the first functional hole 300 and the second functional hole 400.

In an exemplary implementation, an orthographic projection of the first functional hole 300 on the plane of the display region (D1-D2 plane) at least partially overlaps an orthographic projection of the second functional hole 400 on the plane of the display region.

In an exemplary implementation, the orthographic projection of the first functional hole 300 on the plane of the display region may be within a range of the orthographic projection of the second functional hole 400 on the plane of the display region.

In an exemplary implementation, an area of the orthographic projection of the first functional hole 300 on the plane of the display region may be about 70% to 90% of an area of the orthographic projection of the second functional hole 400 on the plane of the display region.

In an exemplary implementation, in a direction away from the first functional hole 300, an edge of the orthographic projection of the second functional hole 400 on the plane of the display region is located on outside an edge of the orthographic projection of the first functional hole 300 on the plane of the display region, and a distance between the edge of the orthographic projection of the first functional hole 300 on the plane of the display region and the edge of the orthographic projection of the second functional hole 400 on the plane of the display region may be about 0.2 mm to 0.4 mm. For example, the distance between the edge of the orthographic projection of the first functional hole 300 on the plane of the display region and the edge of the orthographic projection of the second functional hole 400 on the plane of the display region may be about 0.3 mm.

In an exemplary implementation, in a plane parallel to the display panel, the shapes of the first functional hole 300 and the second functional hole 400 may be any one or more of the following: rectangular, polygonal, circular, and elliptical, and the optical device may be a fingerprint recognition device, a camera device, a 3D imaging device, an infrared sensor, or the like.

In an exemplary implementation, when the shapes of the first functional hole 300 and the second functional hole 400 are circular, a diameter of the second functional hole 400 may be larger than a diameter of the first functional hole 300, and a difference between the diameter of the second functional hole 400 and the diameter of the first functional hole 300 may be about 0.4 mm to 0.8 mm. For example, the difference between the diameter of the second functional hole 400 and the diameter of the first functional hole 300 may be about 0.6 mm.

In an exemplary implementation, the display panel may have a center line O extending in the first direction D1, which may bisect the display panel in the second direction D2, i.e., the center line O may bisect the display region 100 in the second direction D2, and may bisect the bonding region 200 in the second direction D2.

In an exemplary implementation, the orthographic projection of the first functional hole 300 on the plane of the display region at least partially overlaps an orthographic projection of the center line O on the plane of the display region, and the orthographic projection of the second functional hole 400 on the plane of the display region at least partially overlaps the orthographic projection of the center line O on the plane of the display region.

In an exemplary implementation, when the shapes of the first functional hole 300 and the second functional hole 400 are circular, the first functional hole 300 may have a first center, the second functional hole 400 may have a second center, an orthographic projection of the first center of the first functional hole 300 on the plane of the display region may overlap the orthographic projection of the center line O on the plane of the display region, and an orthographic projection of the second center of the second functional hole 400 on the plane of the display region may overlap the orthographic projection of the center line O on the plane of the display region.

Exemplary embodiments of the present disclosure provide a scheme for simultaneously opening functional holes in a display region and a bonding region. For a display panel with a bonding region on an upper side of a display region, the present disclosure provides a functional hole in an overlapping region between the display region and the bonding region after being bent, provides a first functional hole in the display region and a second functional hole in the bonding region, the orthographic projection of the first functional hole on the plane of the display region is within a range of the orthographic projection of the second functional hole on the plane of the display region, and a camera hole for mounting a camera device is formed by combining the first functional hole and the second functional hole. Therefore, not only user habits and appearance requirements are met, but also layout difficulty and structural complexity are reduced. For the rollable display device, since the functional hole is provided in the fixed display region, poor display in the rollable display region is avoided.

FIG. 4 is a schematic diagram of a planar structure of a display region. As shown in FIG. 4, the display region (the fixed display region and the rollable display region) may include a plurality of pixel units P arranged in a matrix manner, at least one pixel unit P may include a first sub-pixel P1 emitting a first color light, a second sub-pixel P2 emitting a second color light, and a third sub-pixel P3 emitting a third color light, each of which may include a pixel drive circuit and a light emitting device. The pixel drive circuit in each of the three sub-pixels is connected with a scan signal line, a data signal line, and a light emitting signal line respectively. The pixel drive circuit is configured to receive a data voltage transmitted by the data signal line and output a corresponding current to the light emitting device under control of the scan signal line and the light emitting signal line. The light emitting device in each of the three sub-pixels is connected to a pixel drive circuit of a sub-pixel where the light emitting device is located, and is configured to emit light with a corresponding brightness in response to a current output by the pixel drive circuit of the sub-pixel where the light emitting device is located.

In an exemplary implementation, the first sub-pixel P1 may be a red sub-pixel emitting red (R) light, the second sub-pixel P2 may be a green sub-pixel emitting green (G) light, and the third sub-pixel P3 may be a blue sub-pixel emitting blue (B) light. In an exemplary embodiment, a sub-pixel in the pixel unit may be in a shape of a rectangle, a rhombus, a pentagon, or a hexagon, etc. The sub-pixels may be arranged side by side horizontally, side by side vertically, or in a manner like a Chinese character “ [symbol] ”, which is not limited in the present disclosure.

In an exemplary embodiment, the pixel unit may include four sub-pixels. For example, the four sub-pixels may include a red sub-pixel, a green sub-pixel, a blue sub-pixel, and a white sub-pixel that emits white (W) light. As another example, the four sub-pixels may include a red sub-pixel, a blue sub-pixel, and two green sub-pixels. The four sub-pixels may be arranged side by side horizontally, side by side vertically, or in a square or a diamond, which is not limited in the present disclosure.

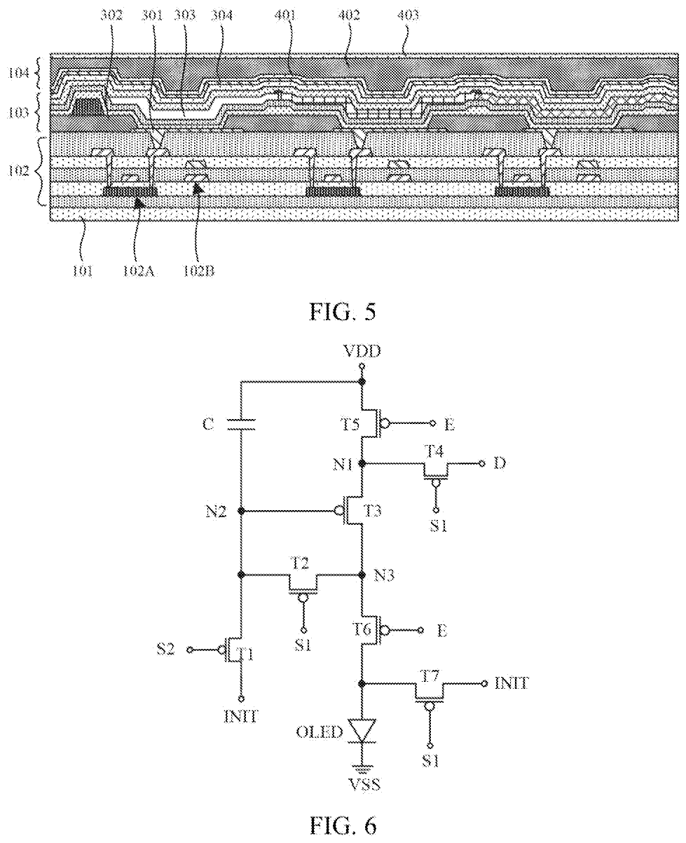

FIG. 5 is a schematic diagram of a sectional structure of a display region, illustrating a structure of the three sub-pixels. As shown in FIG. 5, on a plane perpendicular to the display region, the display region may include a drive structural layer 102 disposed on a substrate 101, a light emitting structural layer 103 disposed on one side of the drive structural layer 102 away from the substrate 101, and an encapsulation structural layer 104 disposed on one side of the light emitting structural layer 103 away from the substrate 101.

In an exemplary implementation, the substrate may be a flexible substrate. The flexible substrate may include a first flexible material layer, a first inorganic material layer, a semiconductor layer, a second flexible material layer and a second inorganic material layer which are stacked. Materials of the first flexible material layer and the second flexible material layer may be polyimide (PI), polyethylene terephthalate (PET) or a polymer soft film with surface treatment, or the like. Materials of the first inorganic material layer and the second inorganic material layer may be silicon nitride (SiNx) or silicon oxide (SiOx), or the like, for improving water and oxygen resistance of the substrate, and a material of the semiconductor layer may be amorphous silicon (a-si).

In an exemplary implementation, the drive structural layer 102 of each sub-pixel may include multiple transistors and storage capacitor(s) that form a pixel drive circuit, an example of which is illustrated in FIG. 4 where each sub-pixel includes one transistor and one storage capacitor. In an exemplary implementation, the drive structural layer 102 of each sub-pixel may include a first insulating layer provided on the substrate; an active layer provided on the first insulating layer; a second insulating layer covering the active layer; a gate electrode and a first capacitor plate provided on the second insulating layer; a third insulating layer covering the gate electrode and the first capacitor plate; a second capacitor plate provided on the third insulating layer; a fourth insulating layer covering the second capacitor plate, wherein the second insulating layer, the third insulating layer and the fourth insulating layer are provided with active vias, and the active vias expose the active layer; a source electrode and a drain electrode provided on the fourth insulating layer, wherein the source electrode and the drain electrode are respectively connected with the active layer through the active vias; a planarization layer covering the above-mentioned structures, wherein a connection via is provided on the planarization layer, and the connection via exposes the drain electrode. The active layer, the gate electrode, the source electrode, and the drain electrode constitute a transistor 102A, and the first capacitor plate and the second capacitor plate constitute a storage capacitor 102B.

In an exemplary implementation, the light emitting structural layer 103 may include an anode 301, a pixel definition layer 302, an organic light emitting layer 303 and a cathode 304. The anode 301 may be provided on the planarization layer and connected with the drain electrode of the transistor 102A through a connection via provided on the planarization layer. The pixel definition layer 302 is arranged on the anode 301, and is provided with a pixel opening exposing the anode 301. The organic light emitting layer 303 is at least partially arranged in the pixel opening, and is connected with the anode 301. The cathode 304 is arranged on the organic light emitting layer 303, and is connected with the organic light emitting layer 303; and the organic light emitting layer 303 emits light of a corresponding color under the driving of the anode 301 and the cathode 304.

In an exemplary implementation, the encapsulation structural layer 104 may include a first encapsulation layer 401, a second encapsulation layer 402, and a third encapsulation layer 403 which are stacked, the first encapsulation layer 401 and the third encapsulation layer 403 may be made of an inorganic material, the second encapsulation layer 402 may be made of an organic material, and the second encapsulation layer 402 is disposed between the first encapsulation layer 401 and the third encapsulation layer 403 to form a stacked structure of an inorganic material/an organic material/an inorganic material, which may ensure that external water vapor cannot enter the light emitting structural layer 103.

In an exemplary implementation, the organic emitting layer 303 may include an Emitting Layer (EML for short) and any one or more of a Hole Injection Layer (HIL), a Hole Transport Layer (HTL), an Electron Block Layer (EBL), a Hole Block Layer (HBL), an Electron Transport Layer (ETL), and an Electron Injection Layer (EIL). In an exemplary embodiment, the hole injection layers, the hole transport layers and the electron block layers of all sub-pixels may be a common layer connected together, the hole block layers, the electron transport layers and the electron injection layers of all sub-pixels may be a common layer connected together, light emitting layers of adjacent sub-pixels may be overlapped slightly, or may be isolated, and electron block layers of adjacent sub-pixels may be overlapped slightly, or may be isolated.

FIG. 6 is a schematic diagram of an equivalent circuit of a pixel drive circuit. In an exemplary implementation, the pixel drive circuit may be of a structure of 3T1C, 4T1C, 5T1C, 5T2C, 6T1C, or 7T1C. As shown in FIG. 6, the pixel drive circuit may include seven transistors (a first transistor T1 to a seventh transistor T7) and one storage capacitor C, and the pixel drive circuit may be connected with seven signal lines (a data signal line D, a first scan signal line S1, a second scan signal line S2, a light emitting signal line E, an initial signal line INIT, a first power line VDD, and a second power line VSS).

In an exemplary implementation, the pixel drive circuit may include a first node N1, a second node N2, and a third node N3. The first node N1 is connected to a first electrode of the third transistor T3, a second electrode of the fourth transistor T4 and a second electrode of the fifth transistor T5 respectively. The second node N2 is connected to a second electrode of the first transistor, a first electrode of the second transistor T2, a control electrode of the third transistor T3 and a second end of the storage capacitor C respectively. The third node N3 is connected to a second electrode of the second transistor T2, a second electrode of the third transistor T3 and a first electrode of the sixth transistor T6 respectively.

In an exemplary implementation, a first end of the storage capacitor C is connected with the first power supply line VDD, and the second end of the storage capacitor C is connected with the second node N2, i.e., the second end of the storage capacitor C is connected with the control electrode of the third transistor T3.

The control electrode of the first transistor T1 is connected to the second scan signal line S2, the first electrode of the first transistor T1 is connected to the initial signal line INIT, and the second electrode of the first transistor is connected to the second node N2. When a scan signal with an on-level is applied to the second scan signal line S2, the first transistor T1 transmits an initialization voltage to the control electrode of the third transistor T3, so as to initialize the quantity of charges of the control electrode of the third transistor T3.

The control electrode of the second transistor T2 is connected to the first scan signal line S1, the first electrode of the second transistor T2 is connected to the second node N2, and the second electrode of the second transistor T2 is connected to the third node N3. When a scan signal with an on-level is applied to the first scan signal line S1, the second transistor T2 enables the control electrode of the third transistor T3 to be connected to the second electrode of the third transistor T3.

The control electrode of the third transistor T3 is connected to the second node N2, i.e., the control electrode of the third transistor T3 is connected to the second end of the storage capacitor C, the first electrode of the third transistor T3 is connected to the first node N1, and the second electrode of the third transistor T3 is connected to the third node N3. The third transistor T3 may be referred to as a drive transistor, and the third transistor T3 determines an amount of a drive current flowing between the first power supply line VDD and the second power supply line VSS according to a potential difference between the control electrode and the first electrode of the third transistor T3.

The control electrode of the fourth transistor T4 is connected to the first scan signal line S1, the first electrode of the fourth transistor T4 is connected to the data signal line D, and the second electrode of the fourth transistor T4 is connected to the first node N1. The fourth transistor T4, may be referred to as a switching transistor, a scanning transistor, etc., and the fourth transistor T4 enables a data voltage of the data signal line D to be input into the pixel drive circuit when a scan signal with an on-level is applied to the first scan signal line S1.

The control electrode of the fifth transistor T5 is connected with the light emitting signal line E, the first electrode of the fifth transistor T5 is connected with the first power supply line VDD, and the second electrode of the fifth transistor T5 is connected with the first node N1. The control electrode of the sixth transistor T6 is connected with the light emitting signal line E, the first electrode of the sixth transistor T6 is connected with the third node N3, and the second electrode of the sixth transistor T6 is connected with the first electrode of the light emitting device. The fifth transistor T5 and the sixth transistor T6 may be referred to as light emitting transistors. When a light emitting signal with an on-level is applied to the light emitting signal line E, the fifth transistor T5 and the sixth transistor T6 enable the light emitting device to emit light by forming a drive current path between the first power supply line VDD and the second power supply line VSS.

The control electrode of the seventh transistor T7 is connected with the first scan signal line S1, the first electrode of the seventh transistor T7 is connected with the initial signal line INIT, and the second electrode of the seventh transistor T7 is connected with the first electrode of the light emitting device. When a scan signal with an on-level is applied to the first scan signal line S1, the seventh transistor T7 transmits an initialization voltage to the first electrode of the light emitting device so as to initialize a charge amount accumulated in the first electrode of the light emitting device or release a charge amount accumulated in the first electrode of the light emitting device.

In an exemplary implementation, the second electrode of the light emitting device is connected with the second power supply line VSS, a signal of the second power supply line VSS is a low-level signal, and a signal of the first power supply line VDD is a high-level signal continuously provided. The first scan signal line S1 is a scan signal line in a pixel drive circuit in a current display row, and the second scan signal line S2 is a scan signal line in a pixel drive circuit in a previous display row, that is, for the n-th display row, the first scan signal line S1 is S(n), and the second scan signal line S2 is S(n−1). The second scan signal line S2 in the pixel drive circuit in the current display row and the first scan signal line S1 in the pixel drive circuit in the previous display row are the same signal line, such that signal lines of a display panel can be reduced, so as to achieve a narrow bezel of the display device.

In an exemplary implementation, the first transistor T1 to the seventh transistor T7 may be P-type transistors, or may be N-type transistors. Use of a same type of transistors in a pixel drive circuit may simplify a process flow, reduce a process difficulty of a display panel, and improve a product yield. In some possible implementations, the first transistor T1 to the seventh transistor T7 may include a P-type transistor and an N-type transistor.

In an exemplary implementation, the first scan signal line S1, the second scan signal line S2, the light emitting signal line E, and the initial signal line INIT extend in a horizontal direction, and the second power supply line VSS, the first power supply line VDD, and the data signal line D extend in a vertical direction.

In an exemplary implementation, the light emitting device may be an Organic Light Emitting Diode (OLED) including a first electrode (anode), an organic emitting layer, and a second electrode (cathode) that are stacked.

FIG. 7 is a working timing diagram of a pixel drive circuit. An exemplary embodiment of the present disclosure will be described below through a working process of the pixel drive circuit illustrated in FIG. 6. The pixel drive circuit in FIG. 6 includes seven transistors (a first transistor T1 to a seventh transistor T7) and one storage capacitor C.

In an exemplary implementation, the working process of the pixel drive circuit may include following stages.

In a first stage A1, referred to as a reset stage, a signal of the second scan signal line S2 is a low-level signal, and signals of the first scan signal line S1 and the light emitting signal line E are high-level signals. The signal of the second scan signal line S2 is a low-level signal, so that the first transistor T1 is turned on, and a signal of the initial signal line INIT is provided to a second node N2 to initialize the storage capacitor C to clear an original data voltage in the storage capacitor. The signals of the first scan signal line S1 and the light emitting signal line E are high-level signals, so that the second transistor T2, the fourth transistor T4, the fifth transistor T5, the sixth transistor T6, and the seventh transistor T7 are turned off. An OLED does not emit light in this stage.

In a second stage A2, referred to as a data writing stage or a threshold compensation stage, a signal of the first scan signal line S1 is a low-level signal, signals of the second scan signal line S2 and the light emitting signal line E are high-level signals, and the data signal line D outputs a data voltage. In this stage, the second end of the storage capacitor C is at a low level, so the third transistor T3 is turned on. The signal of the first scan signal line S1 is the low-level signal, so that the second transistor T2, the fourth transistor T4, and the seventh transistor T7 are turned on. The second transistor T2 and the fourth transistor T4 are turned on, so that the data voltage output by the data signal line D is provided to the second node N2 through the first node N1, the turned-on third transistor T3, the third node N3, and the turned-on second transistor T2, and the storage capacitor C is charged with a difference between the data voltage output by the data signal line D and a threshold voltage of the third transistor T3. A voltage at the second end (the second node N2) of the storage capacitor C is Vd−|Vth|, wherein Vd is the data voltage output by the data signal line D, and Vth is the threshold voltage of the third transistor T3. The seventh transistor T7 is turned on, so that an initialization voltage of the initial signal line INIT is provided to a first electrode of the OLED to initialize (reset) the first electrode of the OLED and clear a pre-stored voltage therein, thereby completing initialization to ensure that the OLED does not emit light. A signal of the second scan signal line S2 is a high-level signal, so that the first transistor T1 is turned off. The signal of the light emitting signal line E is a high-level signal, so that the fifth transistor T5 and the sixth transistor T6 are turned off.

In a third stage A3, referred to as a light emitting stage, a signal of the light emitting signal line E is a low-level signal, and signals of the first scan signal line S1 and the second scan signal line S2 are high-level signals. The signal of the light emitting signal line E is a low-level signal, so that the fifth transistor T5 and the sixth transistor T6 are turned on, and a power voltage output by the first power supply line VDD provides a drive voltage to the first electrode of the OLED through the turned-on fifth transistor T5, third transistor T3, and sixth transistor T6 to drive the OLED to emit light.

In a drive process of the pixel drive circuit, a drive current flowing through the third transistor T3 (drive transistor) is determined by a voltage difference between a gate electrode and a first electrode of the third transistor T3. The voltage of the second node N2 is Vdata−|Vth|, so the drive current of the third transistor T3 is as follows.

I=K*(Vgs−Vth)²=K*[(Vdd−Vd+|Vth|)−Vth]²=K*[(Vdd−Vd]²

Herein, I is the drive current flowing through the third transistor T3, i.e., a drive current for driving the OLED, K is a constant, Vgs is the voltage difference between the gate electrode and the first electrode of the third transistor T3, Vth is the threshold voltage of the third transistor T3, Vd is the data voltage output by the data signal line D, and Vdd is the power voltage output by the first power supply line VDD.

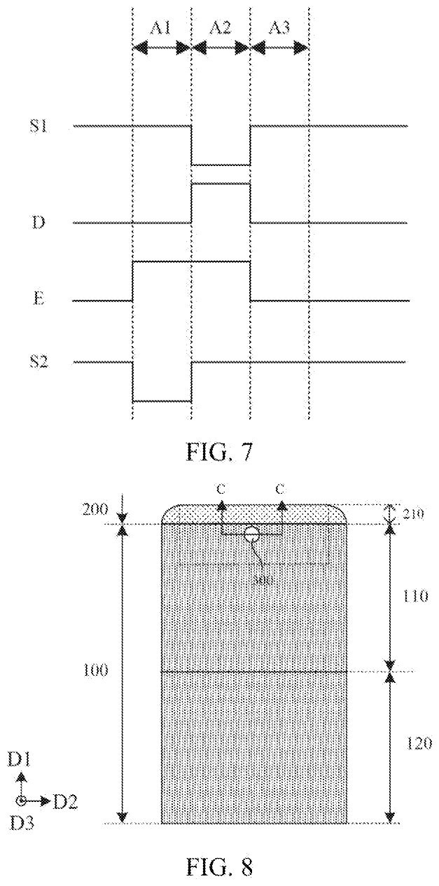

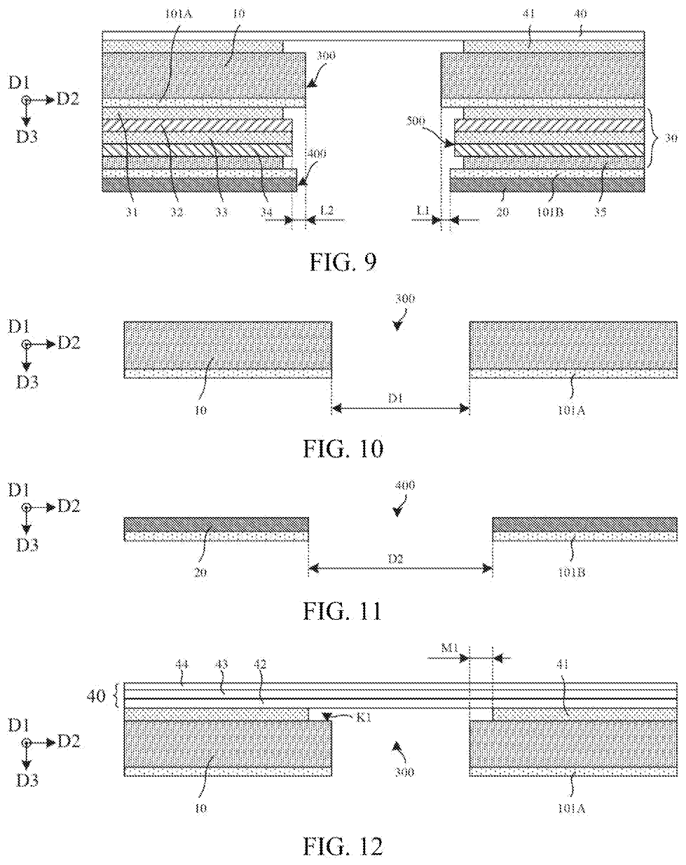

FIG. 8 is a schematic diagram of a planar structure of a display panel in a bent state according to an exemplary embodiment of the present disclosure, illustrating a state after the bonding region is bent, and FIG. 9 is a sectional view taken along C-C in FIG. 8. As shown in FIGS. 8 and 9, on a plane perpendicular to the display region, a display panel in an overlapping region between the display region and the bonding region includes: a display substrate 101A, a display structural layer 10 disposed on a side of the display substrate 101A in an opposite direction of the third direction D3, a cover plate layer 40 disposed on a side of the display structural layer 10 away from the display substrate, a reinforcement structural layer 30 disposed on a side of the display substrate 101A in the third direction D3, a bonding substrate 101B disposed on a side of the reinforcement structural layer 30 away from the display substrate, and a bonding structural layer 20 disposed on a side of the bonding substrate 101B away from the display substrate.

In an exemplary implementation, a first functional hole 300 which may be a via penetrating through the display substrate 101A and the display structural layer 10 is provided on the display substrate 101A and the display structural layer 10.

In an exemplary implementation, a second functional hole 400 which may be a via penetrating through the bonding substrate 101B and the bonding structural layer 20 is provided on the bonding substrate 101B and the bonding structural layer 20.

In an exemplary implementation, the reinforcement structural layer 30 is provided with a first structural hole 500 which may be a via penetrating through the first structural hole 500.

In an exemplary implementation, the first functional hole 300 is communicated with the first structural hole 500, and the first structural hole 500 is communicated with the second functional hole 400, so that the first functional hole 300, the first structural hole 500, and the second functional hole 400 are combined into a camera hole of a via structure, and an optical device may be disposed in the camera hole.

In an exemplary implementation, the reinforcement structural layer 30 may include a first adhesive layer 31 disposed on a side of the display substrate 101A away from the display structural layer 10, a first reinforcement layer 32 disposed on a side of the first adhesive layer 31 away from the display substrate 101A, a second adhesive layer 33 disposed on a side of the first reinforcement layer 32 away from the display substrate 101A, a second reinforcement layer 34 disposed on a side of the second adhesive layer 33 away from the display substrate 101A, and a bending spacer layer 35 disposed on a side of the second reinforcement layer 34 away from the display substrate 101A.

In an exemplary implementation, the bonding substrate 101B of the bonding region bent to the back of the display region is attached to a side of the bending spacer layer 35 away from the display substrate 101A, and the bonding structural layer 20 of the bonding region is disposed on a side of the bonding substrate 101B away from the display substrate 101A.

In an exemplary implementation, the display structural layer 10 of the display region may include an array structural layer disposed on the display substrate 101A, a light emitting structural layer disposed on a side of the array structural layer away from the display substrate 101A, and an encapsulation structural layer disposed on a side of the light emitting structural layer away from the display substrate 101A.

In an exemplary implementation, the cover plate layer 40 may be attached to a side of the display structural layer 10 of the display region away from the display substrate 101A by a cover plate adhesive layer 41 provided with a cover plate adhesive hole that is communicated with the first functional hole 300.

In an exemplary implementation, an orthographic projection of the first functional hole 300 on the plane of the display region may be within a range of an orthographic projection of the second functional hole 400 on the plane of the display region.

In an exemplary implementation, an edge of the orthographic projection of the second functional hole 400 on the plane of the display region is located on outside an edge of the orthographic projection of the first functional hole 300 on the plane of the display region in a direction away from the first functional hole 300, and a first distance L1 between the edge of the orthographic projection of the second functional hole 400 on the plane of the display region and the edge of the orthographic projection of the first functional hole 300 on the plane of the display region may be about 0.2 mm to 0.4 mm.

In an exemplary implementation, the orthographic projection of the first functional hole 300 on the plane of the display region may be within a range of an orthographic projection of the first structural hole 500 on the plane of the display region.

In an exemplary implementation, an edge of the orthographic projection of the first structural hole 500 on the plane of the display region is located on outside the edge of the orthographic projection of the first functional hole 300 on the plane of the display region in a direction away from the first functional hole 300, and a second distance L2 between the edge of the orthographic projection of the first structural hole 500 on the plane of the display region and the edge of the orthographic projection of the first functional hole 300 on the plane of the display region may be about 0.2 mm to 0.8 mm.

In an exemplary implementation, the orthographic projection of the second functional hole 400 on the plane of the display region may be within the range of the orthographic projection of the first structural hole 500 on the plane of the display region.

In an exemplary implementation, the second distance L2 may be greater than or equal to the first distance L1.

A preparation process of the display panel will be exemplarily described below. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation and chemical vapor deposition, the coating may be any one or more of spray coating, spin coating and inkjet printing, and the etching may be any one or more of dry etching and wet etching, the present disclosure is not limited thereto. A “thin film” refers to a layer of thin film made of a certain material on a substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are provided on a same layer” described in the present disclosure means that A and B are formed at the same time through a same patterning process, and a “thickness” of a film layer is a dimension of the film layer in a direction perpendicular to a display panel. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In an exemplary implementation, by taking the fixed display region as an example, the preparation process of the display panel according to an exemplary embodiment of the present disclosure may include the following operations.

(1) Forming a display structural layer and a bonding structural layer of the display panel. In an exemplary implementation, the forming a display structural layer and a bonding structural layer of the display panel may include following operations.

(A1) Forming a drive structural layer of the display region and a corresponding film layer of the bonding region. In an exemplary embodiment, the forming a drive structural layer of the display region and a corresponding film layer of the bonding region may include: forming a first insulating layer on a substrate and a pattern of a semiconductor layer disposed on the first insulating layer, forming a second insulating layer covering the pattern of the semiconductor layer and a pattern of a first conductive layer disposed on the second insulating layer, forming a third insulating layer covering the pattern of the first conductive layer and a pattern of a second conductive layer disposed on the third insulating layer, forming a fourth insulating layer covering the pattern of the second conductive layer and a pattern of a third conductive layer disposed on the fourth insulating layer, and forming a pattern of a planarization layer covering the pattern of the third conductive layer.

In an exemplary implementation, the pattern of the semiconductor layer may include at least a plurality of active layers located in each sub-pixel of the display region, the pattern of the first conductive layer may include at least a plurality of gate electrodes and first plates located in each sub-pixel of the display region, the pattern of the second conductive layer may include at least a plurality of second plates located in each sub-pixel of the display region, and the pattern of the third conductive layer may include at least a plurality of source electrodes and drain electrodes located in each sub-pixel of the display region.

In an exemplary implementation, the pattern of the first conductive layer, the pattern of the second conductive layer, and the pattern of the third conductive layer may include a plurality of fanout lines and power lines located in the bonding region, which is not limited in the present disclosure.

In an exemplary implementation, in the aforementioned process, a groove may be formed in a bending region of the bonding region, the first insulating layer, the second insulating layer, the third insulating layer, and the fourth insulating layer in the groove are removed, and the groove is configured to bend the composite circuit region in the bonding region to the back of the display region.

In an exemplary implementation, the first insulating layer, the second insulating layer, the third insulating layer, and the fourth insulating layer may be made of any one or more of Silicon Oxide (SiOx), Silicon Nitride (SiNx), and Silicon Oxynitride (SiON), and may be a single layer, a multi-layer, or a composite layer. The first insulating layer may be referred to as a Buffer layer, the second insulating layer and the third insulating layer may be referred to as Gate insulator (GI) layers, and the fourth insulating layer may be referred to as an Interlayer Dielectric (ILD) layer. The first conductive layer, the second conductive layer, and the third conductive layer may be made of a metal material, such as any one or more of Silver (Ag), Copper (Cu), Aluminum (Al), Titanium (Ti), and Molybdenum (Mo), or an alloy material of the aforementioned metals, such as an Aluminum Neodymium alloy (AlNd) or a Molybdenum Niobium alloy (MoNb), and may be of a single-layer structure or a multi-layer composite structure, such as Ti/Al/Ti. The planarization layer may be made of an organic material such as resin. The semiconductor layer may be made of various materials, such as amorphous Indium Gallium Zinc Oxide (a-IGZO), Zinc Oxynitride (ZnON), Indium Zinc Tin Oxide (IZTO), amorphous Silicon (a-Si), polycrystalline Silicon (p-Si), sexithiophene, and polythiophene. That is, the present disclosure is applicable to transistors manufactured based on an oxide technology, a silicon technology, and an organic matter technology.

In an exemplary implementation, the substrate may be a flexible substrate, the flexible substrate may be made of a material such as polyimide (PI), the flexible substrate may be a single-layer structure, or the flexible substrate may be a stacked structure composed of an inorganic material layer and a flexible material layer, which is not limited in the present disclosure.

(B1) Forming a light emitting structural layer of the display region and a corresponding film layer of the bonding region. In an exemplary embodiment, the forming a light emitting structural layer of the display region and a corresponding film layer of the bonding region may include: sequentially forming a fourth conductive layer, a pixel definition layer, an organic light emitting layer, and a cathode on the basis of the aforementioned film layer structures.

In an exemplary implementation, the fourth conductive layer may include at least a plurality of anodes located in each sub-pixel of the display region, the pixel definition layer may include at least a pixel opening located in each sub-pixel of the display region, the pixel opening exposes the anode of the sub-pixel where the pixel opening is located, the organic light emitting layer in each sub-pixel of the display region is connected to the anode through the pixel opening of the sub-pixel where the organic light emitting layer is located, and the cathode may be of a full-surface structure connected to the organic light emitting layer in each sub-pixel.

In an exemplary implementation, a structure such as an isolation dam may be formed in the bonding region during the aforementioned process, which is not limited in the present disclosure.

In an exemplary implementation, the fourth conductive thin film may be made of a metal material or a transparent conductive material, and the metal material may include any one or more of silver (Ag), copper (Cu), aluminum (Al), titanium (TI), and molybdenum (Mo), or an alloy material of the above metals, and the transparent conductive material may include Indium Tin Oxide (ITO) or Indium Zinc Oxide (IZO). In an exemplary implementation, the conductive thin film may have a single-layer structure or a multi-layer composite structure, such as ITO/Al/ITO. The material of the pixel definition layer may include polyimide, acrylic or the like, and the cathode may be any one or more of magnesium (Mg), silver (Ag), aluminum (Al), copper (Cu) and lithium (Li), or an alloy made of any one or more of the above metals.

In an exemplary implementation, a pattern of an optical coupling layer may be formed after a pattern of a cathode is formed. The optical coupling layer is disposed on the cathode. A refractive index of the optical coupling layer may be greater than a refractive index of the cathode, which is beneficial to light extraction and increasing a light exit efficiency. The optical coupling layer may be made of an organic material, or made of an inorganic material, or made of an organic material and an inorganic material, and may be a single layer, a multi-layer, or a composite layer, the present disclosure is not limited thereto.

(C1) Forming an encapsulation structural layer. In an exemplary embodiment, forming an encapsulation structural layer may include: first forming a pattern of a first encapsulation layer in a deposition manner using an open mask on the substrate on which the above-mentioned patterns are formed, then forming a pattern of a second encapsulation layer using an inkjet printing process and an open mask, and then forming a pattern of a third encapsulation layer in a deposition manner using an open mask, wherein the first encapsulation layer, the second encapsulation layer and the third encapsulation layer which are stacked constitute the encapsulation structural layer.

In an exemplary embodiment, the first encapsulation layer and the third encapsulation layer may be made of any one or more of the following: Silicon Oxide (SiOx), Silicon Nitride (SiNx), and Silicon Oxynitride (SiON), may be a single layer, a multi-layer, or a composite layer, which can ensure that external water and oxygen cannot enter the light emitting structural layer, and the deposition manner may be Chemical Vapor Deposition (CVD) or Atomic Layer Deposition (ALD). The second encapsulation layer may be made of an organic material, such as resin, etc., playing a role of covering various film layers of the display panel so as to improve structural stability and flatness. The stacked structure of an inorganic material/an organic material/an inorganic material formed by the encapsulation structural layer can ensure encapsulation to be integrity and effectively isolate the external water and oxygen. In an exemplary implementation, the encapsulation structural layer may be provided in the lead regions of the display region and the bonding region.

In an exemplary implementation, after the encapsulation structural layer is formed, a corresponding Functional Layer (FL) may be formed. For example, the functional layer may be a touch structural layer (TSP), and the touch structural layer may include a touch electrode layer or include a touch electrode layer and a touch insulating layer, etc., the present disclosure is not limited thereto.

(D1) Forming an anti-reflection layer. In an exemplary embodiment, the forming an anti-reflection layer may include forming an anti-reflection layer on the encapsulation structural layer.

In an exemplary implementation, the anti-reflection layer may employ a polarizer disposed only in the display region. The polarizer may be formed using a patterning process, or the polarizer may be an attached polarizer, and the thickness of the polarizer layer may be from about 55 μm to 75 μm. For example, the thickness of the polarizer layer may be about 66 μm.

Hereto, the display structural layer and the bonding structural layer of the display panel are prepared. The display structural layer may be located in the display region, and the bonding structural layer may be located in the bonding region.

In an exemplary implementation, the display structural layer and the bonding structural layer in the rollable display region may be substantially the same as the display structural layer and the bonding structural layer in the fixed display region.

(2) Forming a pattern of a functional hole. In an exemplary embodiment, the forming the pattern of the functional hole may include: forming a first functional hole 300 and a second functional hole 400 in the display region and the bonding region, respectively, in a laser punching manner, as shown in FIGS. 10 and 11. FIG. 10 is a sectional view taken along A-A in FIG. 2, and FIG. 11 is a sectional view taken along B-B in FIG. 2.

As shown in FIG. 10, the display region may include a display substrate 101A and a display structural layer 10 provided on a side of the display substrate 101A in an opposite direction of the third direction D3, and the display substrate 101A and the display structural layer 10 in the first functional hole 300 are removed to form a via structure.

In an exemplary implementation, the display structural layer 10 may include a drive structural layer disposed on the display substrate, a light emitting structural layer disposed on a side of the drive structural layer away from the display substrate, an encapsulation structural layer disposed on a side of the light emitting structural layer away from the display substrate, and an anti-reflection layer disposed on a side of the encapsulation structural layer away from the display substrate.

As shown in FIG. 11, the composite circuit region of the bonding region may include a bonding substrate 101B and a bonding structural layer 20 provided on a side of the bonding substrate 101B in an opposite direction of the third direction D3, and the bonding substrate 101B and the bonding structural layer 20 in the second functional hole 400 are removed to form a via structure.

In an exemplary implementation, the bonding structural layer 20 may include an insulating layer structure disposed on the bonding substrate and corresponding signal lines disposed in the insulating layer structure, the insulating layer structure may include any one or more of the following: a first insulating layer, a second insulating layer, a third insulating layer, a fourth insulating layer and a planarization layer, and the corresponding signal lines may include any one or more of the following: fanout lines, touch leads, high-level signal lines (VDD) and low-level signal lines (VSS).

In an exemplary implementation, the display substrate 101A of the display region and the bonding substrate 101B of the bonding region may be of an interconnected integral structure of the same material and the same thickness.

In an exemplary implementation, forming the first functional hole 300 and the second functional hole 400 in a laser punching manner may reduce crack defects around the holes. By arranging corresponding avoidance among some signal lines in the display region and the bonding region, it may balance the loadings of the signal lines near the first functional hole 300 and the second functional hole 400, so that the resistances of the signal lines near the first functional hole 300 and the second functional hole 400 are substantially the same, thus avoiding poor color deviation due to the difference in the loadings of the signal lines.

In an exemplary implementation, laser punching may be performed first in the bonding region to form the second functional hole 400, and then laser punching may be performed in the display region to form the first functional hole 300. The position of the first functional hole 300 in the display region and the position of the second functional hole 400 in the bonding region may be arranged according to the alignment relationship, such that after the bonding region is bent to the back of the display region, the position of the first functional hole 300 corresponds to the position of the second functional hole 400, and the orthographic projection of the first functional hole 300 on the plane of the display region in the display panel is within the range of the orthographic projection of the second functional hole 400 on the plane of the display region in the display panel.

In an exemplary implementation, an area of the second functional hole 400 may be larger than an area of the first functional hole 300.

In an exemplary implementation, the area of the first functional hole 300 may be about 70% to 90% of the area of the second functional hole 400.

In an exemplary implementation, when the shapes of the first functional hole 300 and the second functional hole 400 are circular, the second diameter D2 of the second functional hole 400 may be larger than the first diameter D1 of the first functional hole 300, and the difference between the second diameter D2 of the second functional hole 400 and the first diameter D1 of the first functional hole 300 may be about 0.4 mm to 0.8 mm. For example, the difference between the second diameter D2 and the first diameter D1 may be about 0.6 mm, that is, the difference between the radius of the second functional hole 400 and the radius of the first functional hole 300 may be about 0.3 mm. In an exemplary implementation, the first diameter D1 of the first functional hole 300 may be about 3 mm.

In an exemplary implementation, the display panel may have a center line extending in the first direction D1 that bisects the display panel in the second direction D2. The first center of the circular first functional hole 300 and the second center of the second functional hole 400 may both be located on the center line, such that the first functional hole 300 is disposed symmetrically about the center line and the second functional hole 400 is disposed symmetrically about the center line. By arranging both the first functional hole 300 and the second functional hole 400 symmetrically relative to the center line of the display panel, the present disclosure can ensure that the loadings of the signal lines around the first functional hole 300 and the second functional hole 400 are substantially same and the impedances of the signal lines around the first functional hole 300 and the second functional hole 400 are substantially same, thereby avoiding poor color deviation due to the difference in the loadings of the signal lines and ensuring the display effect.

(3) Forming a cover plate layer. In an exemplary embodiment, forming the cover plate layer may include: first affixing a functional layer 42 and a plastic cover plate 43 together to form a flexible cover plate, then adhering the flexible cover plate to the display structural layer 10 through the cover plate adhesive layer 41, and then affixing the protective layer 44 on the flexible cover plate, wherein the functional layer 42, the plastic cover plate 43 and the protective layer 44 together form the cover plate layer 40, as shown in FIG. 12, which is a sectional view taken along A-A in FIG. 2.

In an exemplary implementation, the cover plate adhesive layer 41 may be made of an optical adhesive (OCA), and the thickness of the cover plate adhesive layer 41 may be about 15 μm to 35 μm. For example, the thickness of the cover plate adhesive layer 41 may be about 25 μm.

In an exemplary implementation, the functional layer 42 may be made of polyethylene terephthalate (PET), and the thickness of the functional layer 42 may be from about 47 μm to 67 μm. For example, the thickness of the functional layer 42 may be about 57 μm.

In an exemplary implementation, the plastic cover plate 43 may be made of plastic-based Colorless Polyimide (CPI) having flexible characteristic, and the thickness of the plastic cover plate 43 may be about 80 μm to 100 μm. For example, the thickness of the plastic cover plate 43 may be about 90 μm.

In an exemplary implementation, the thickness of the protective (PF) layer 44 may be about 40 μm to 60 μm. For example, the thickness of the protective layer 44 may be about 50 μm. In an exemplary embodiment, the protective layer is configured to protect a structure such as a cover plate during preparation of the display panel, and may be torn off during use of the display panel.

In an exemplary implementation, considering that the rollable display device includes a rollable display region and the cover plate is required to have characteristics such as flexibility, light transmittance, and wear resistance at the same time, the flexible cover plate of the exemplary embodiment of the present disclosure adopts a plastic-based colorless polyimide having flexible characteristic. Polyimide (PI) is an organic material with excellent thermal stability, chemical stability and dielectric characteristics. Transparent polyimide (PI) formed through treatments, such as, introduction of strong electronegative groups, alicyclic structure, large substituted groups, asymmetric and rigid non-coplanar structure and polymerizable inorganic nanoparticles, overcomes the shortcomings of the traditional polyimide with a light yellow or dark yellow color. In an exemplary embodiment, a hard film (HC) may be plated on the colorless polyimide, which can improve the impact resistance of the display panel. In one possible exemplary embodiment, the cover plate may be made of a rigid material such as Cover Glass (CG), the present disclosure is not limited thereto.

In an exemplary implementation, the functional layer in the flexible cover plate and the plastic cover plate may be a single layer or may be a multi-layer, the present disclosure is not limited thereto.

In an exemplary implementation, the cover plate adhesive layer 41 and the cover plate layer 40 are disposed in the display region (the fixed display region and the rollable display region, and the structure, material and parameters of the cover plate layer in the rollable display region may be substantially the same as those of the cover plate layer in the fixed display region), there is no cover plate adhesive layer 41 and cover plate layer 40 in the bonding region, and the structure of the bonding region after this process is substantially similar to that after the process of forming functional holes.

In an exemplary implementation, the cover plate adhesive layer 41 is disposed on the display structural layer 10 in a region other than the first functional hole 300. At the position corresponding to the first functional hole 300, the cover plate adhesive layer 41 is formed with a cover plate adhesive hole K1, and the cover plate adhesive hole K1 may be a via structure penetrating through the cover plate adhesive layer 41.

In an exemplary implementation, the position of the cover plate adhesive hole K1 may correspond to the position of the first functional hole 300, the shape of the cover plate adhesive hole K1 may be substantially identical to the shape of the first functional hole 300, and the orthographic projection of the first functional hole 300 on the plane of the display region may be within a range of the orthographic projection of the cover plate adhesive hole K1 on the plane of the display region to ensure that the cover plate adhesive layer 41 may expose the first functional hole 300 after the cover plate adhesive layer 41 is formed.

In an exemplary implementation, an edge of the orthographic projection of the cover plate adhesive hole K1 on the plane of the display region may be located on outside an edge of the orthographic projection of the first functional hole 300 on the plane of the display region in a direction away from the first functional hole 300, and a first expansion distance M1 between the edge of the orthographic projection of the cover plate adhesive hole K1 on the plane of the display region and the edge of the orthographic projection of the first functional hole 300 on the plane of the display region may be about 0.2 mm to 0.8 mm, i.e., the cover plate adhesive hole K1 is expanded from 0.2 mm to 0.8 mm relative to the first functional hole 300. For example, the first expansion distance M1 may be about 0.5 mm taking into account equipment capabilities and alignment tolerances.

In an exemplary implementation, the cover plate layer 40 may cover the entire display region, i.e., the cover plate layer 40 covers a region where the first functional hole 300 is located.

Hereto, a film structure on a side of an upper surface of the display panel (in an opposite direction of the third direction D3) is prepared. In an exemplary embodiment, the display region of the display panel may include a display structural layer 10 disposed on the display substrate 101A, a cover plate adhesive layer 41 disposed on a side of the display structural layer 10 away from the display substrate, and a cover plate layer 40 disposed on a side of the cover plate adhesive layer 41 away from the display substrate, a first functional hole 300 with a via structure is formed on the display substrate 101A and the display structural layer 10, and a cover plate adhesive hole K1 with a via structure is formed on the cover plate adhesive layer 41, the cover plate adhesive hole K1 is communicated with the first functional hole 300. The bonding region of the display panel may include a bonding structural layer 20 provided on the bonding substrate 101B, a second functional hole 400 with a via structure is formed on the bonding substrate 101B and the bonding structural layer 20.

(4) Forming a pattern of a strengthening structural layer of the display panel. In an exemplary embodiment, forming the pattern of the strengthening structural layer may include following operations.

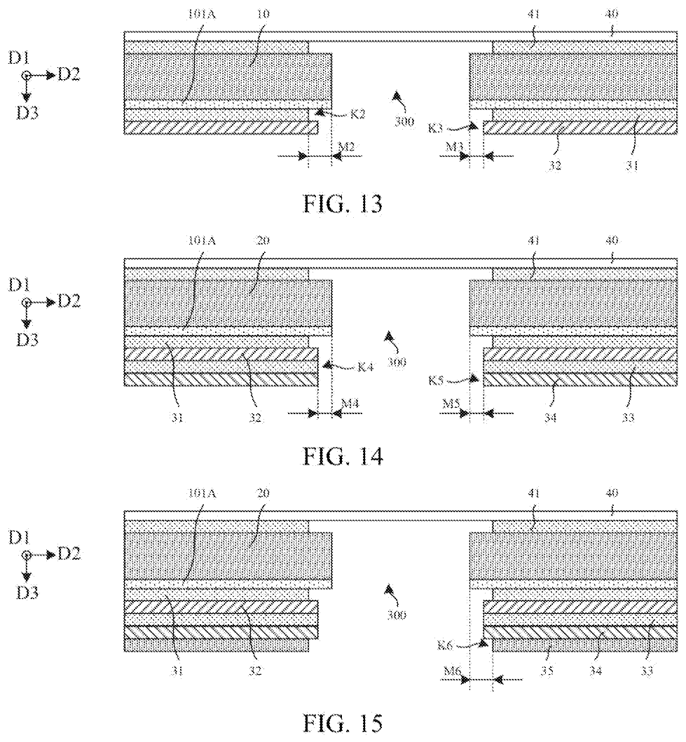

(A2) Attaching a first reinforcement layer. In an exemplary embodiment, the attaching the first reinforcement layer may include: adhering the first reinforcement layer 32 to a side of the display substrate 101A in the third direction D3 (a side of the display substrate 101A away from the display structural layer 10) by the first adhesive layer 31, as shown in FIG. 13, which is a sectional view taken along A-A in FIG. 2.

In an exemplary implementation, the first adhesive layer 31 and the first reinforcement layer 32 are provided in the display region, there is no first adhesive layer 31 and no first reinforcement layer 32 in the bonding region, and the structure of the bonding region after this process is substantially similar to that after the process of forming the functional hole.

In an exemplary implementation, the first adhesive layer 31 may be made of an optical adhesive (OCA), the first adhesive layer 31 is disposed on the display substrate 101A in a region other than the first functional hole 300, and the thickness of the first adhesive layer 31 may be about 40 μm to 60 μm. For example, the thickness of the first adhesive layer 31 may be about 50 μm. At the position corresponding to the first functional hole 300, the first adhesive layer 31 is formed with a first adhesive hole K2, and the first adhesive hole K2 may be a via structure penetrating through the first adhesive layer 31.

In an exemplary implementation, the position of the first adhesive hole K2 may correspond to the position of the first functional hole 300, the shape of the first adhesive hole K2 may be substantially the same as the shape of the first functional hole 300, and the orthographic projection of the first functional hole 300 on the plane of the display region may be within a range of an orthographic projection of the first adhesive hole K2 on the plane of the display region to ensure that the first adhesive layer 31 may expose the first functional hole 300 after the first adhesive layer 31 is formed.

In an exemplary implementation, the edge of the orthographic projection of the first adhesive hole K2 on the plane of the display region may be located on outside the edge of the orthographic projection of the first functional hole 300 on the plane of the display region in a direction away from the first functional hole 300, and a second expansion distance M2 between the edge of the orthographic projection of the first adhesive hole K2 on the plane of the display region and the edge of the orthographic projection of the first functional hole 300 on the plane of the display region may be about 0.2 mm to 0.8 mm, i.e., the first adhesive hole K2 is expanded from 0.2 mm to 0.8 mm relative to the first functional hole 300. For example, the second expansion distance M2 may be about 0.5 mm taking into account equipment capabilities and alignment tolerances.

In an exemplary implementation, the first reinforcement layer 32 may be made of stainless steel (SUS), the first reinforcement layer 32 is disposed in a region other than the first functional hole 300, and the thickness of the first reinforcement layer 32 may be about 20 μm to 40 μm. For example, the thickness of the first reinforcement layer 32 may be about 30 μm. At the position corresponding to the first functional hole 300, the first reinforcement layer 32 is formed with a first reinforcement hole K3, and the first reinforcement hole K3 may be a via structure penetrating through the first reinforcement layer 32.

In an exemplary implementation, the position of the first reinforcement hole K3 may correspond to the position of the first functional hole 300, the shape of the first reinforcement hole K3 may be substantially the same as the shape of the first functional hole 300, and the orthographic projection of the first functional hole 300 on the plane of the display region may be within a range of an orthographic projection of the first reinforcement hole K3 on the plane of the display region to ensure that the first reinforcement layer 32 can expose the first functional hole 300 after the first reinforcement layer 32 is formed.

In an exemplary implementation, in a direction away from the first functional hole 300, an edge of the orthographic projection of the first reinforcement hole K3 on the plane of the display region may be located on outside the edge of the orthographic projection of the first functional hole 300 on the plane of the display region, and a third expansion distance M3 between the edge of the orthographic projection of the first reinforcement hole K3 on the plane of the display region and the edge of the orthographic projection of the first functional hole 300 on the plane of the display region may be about 0.2 mm to 0.5 mm, i.e., the first reinforcement hole K3 is expanded from 0.2 mm to 0.5 mm relative to the first functional hole 300. For example, taking into account equipment capabilities and alignment tolerances, the third expansion distance M3 may be about 0.4 mm.

In an exemplary implementation, the second expansion distance M2 may be greater than or equal to the third expansion distance M3, which may be greater than a distance between the edge of the orthographic projection of the first functional hole on the plane of the display region and the edge of the orthographic projection of the second functional hole on the plane of the display region.

In an exemplary implementation, the first reinforcement layer may be a full-face structure to increase the strength of the strengthening structural layer. In another exemplary embodiment, the first reinforcement layer may be a patterned structure provided with a hollowed-out region to improve flexibility of the strengthening structural layer while ensuring strength of the strengthening structural layer. For example, a plurality of strip grooves may be provided on the first reinforcement layer, each strip groove may extend along the second direction, and the plurality of strip grooves may be sequentially provided along the first direction. As another example, a plurality of block grooves may be arranged on the first reinforcement layer, and the plurality of block grooves are arranged in a matrix mode on the first reinforcement layer to form a grid structure, and the shapes of the block grooves may be any one or more of the following: square, rectangle, pentagon, hexagon, circle and ellipse. For another example, the strip groove or block groove may be a via penetrating through the first reinforcement layer, or may be a blind hole provided in the first reinforcement layer.

(B2) Attaching a second reinforcement layer. In an exemplary embodiment, the attaching the second reinforcement layer may include: adhering the second reinforcement layer 34 to a side of the first reinforcement layer 32 away from the display substrate through the second adhesive layer 33, as shown in FIG. 14, which is a sectional view taken along A-A in FIG. 2.

In an exemplary implementation, the second adhesive layer 33 and the second reinforcement layer 34 are provided in the display region, there is no second adhesive layer 33 and no second reinforcement layer 34 in the bonding region, and the structure of the bonding region after this process is substantially similar to that after the process of forming the functional hole.

In an exemplary implementation, the second adhesive layer 33 may be made of an optical adhesive (OCA), the second adhesive layer 33 may be disposed on the display substrate 101A in a region other than the first functional hole 300, and the thickness of the second adhesive layer 33 may be about 40 μm to 60 μm. For example, the thickness of the second adhesive layer 33 may be about 50 μm. At the position corresponding to the first functional hole 300, the second adhesive layer 33 is formed with a second adhesive hole K4, and the second adhesive hole K4 may be a via structure penetrating through the second adhesive layer 33.

In an exemplary implementation, the position of the second adhesive hole K4 may correspond to the position of the first functional hole 300, the shape of the second adhesive hole K4 may be substantially the same as the shape of the first functional hole 300, and the orthographic projection of the first functional hole 300 on the plane of the display region may be within a range of an orthographic projection of the second adhesive hole K4 on the plane of the display region to ensure that the second adhesive layer 33 may expose the first functional hole 300 after the second adhesive layer 33 is formed.

In an exemplary implementation, the edge of the orthographic projection of the second adhesive hole K4 on the plane of the display region may be located on outside the edge of the orthographic projection of the first functional hole 300 on the plane of the display region in a direction away from the first functional hole 300, and a fourth expansion distance M4 between the edge of the orthographic projection of the second adhesive hole K4 on the plane of the display region and the edge of the orthographic projection of the first functional hole 300 on the plane of the display region may be about 0.2 mm to 0.5 mm, i.e., the second adhesive hole K4 is expanded 0.2 mm to 0.5 mm relative to the first functional hole 300. For example, taking into account equipment capabilities and alignment tolerances, the fourth expansion distance M4 may be about 0.4 mm.

In an exemplary implementation, the second reinforcement layer 34 may be made of stainless steel (SUS), the second reinforcement layer 34 may be disposed in a region other than the first functional hole 300, and the thickness of the second reinforcement layer 34 may be about 150 to 250 μm. For example, the thickness of the second reinforcement layer 34 may be about 200 μm. A second reinforcement hole K5 is formed in the second reinforcement layer 34 at a position corresponding to the first functional hole 300, and the second reinforcement hole K5 may be a via structure penetrating through the second reinforcement layer 34.

In an exemplary implementation, the position of the second reinforcement hole K5 may correspond to the position of the first functional hole 300, the shape of the second reinforcement hole K5 may be substantially the same as the shape of the first functional hole 300, and the orthographic projection of the first functional hole 300 on the plane of the display region is within a range of an orthographic projection of the second reinforcement hole K5 on the plane of the display region, so as to ensure that the second reinforcement layer 34 may expose the first functional hole 300 after the second reinforcement layer 34 is formed.

In an exemplary implementation, an edge of the orthographic projection of the second reinforcement hole K5 on the plane of the display region is located on outside the edge of the orthographic projection of the first functional hole 300 on the plane of the display region in a direction away from the first functional hole 300, and a fifth expansion distance M5 between the edge of the orthographic projection of the second reinforcement hole K5 on the plane of the display region and the edge of the orthographic projection of the first functional hole 300 on the plane of the display region may be about 0.2 mm to 0.5 mm, i.e., the second reinforcement hole K5 is expanded 0.2 mm to 0.5 mm relative to the first functional hole 300. For example, taking into account equipment capabilities and alignment tolerances, the fifth expansion distance M5 may be about 0.4 mm.

In an exemplary implementation, the third expansion distance M3, the fourth expansion distance M4 and the fifth expansion distance M5 may be substantially the same.

In an exemplary implementation, the second reinforcement layer may be a full-face structure to increase the strength of the strengthening structural layer. In another exemplary implementation, the second reinforcement layer may be a patterned structure provided with a hollowed-out region.

In an exemplary implementation, the materials of the first and second reinforcement layers may be the same, or the materials of the first and second reinforcement layers may be different; one of the first reinforcement layer and the second reinforcement layer is a patterned structure provided with a hollowed-out region, or both of the first reinforcement layer and the second reinforcement layer are patterned structures provided with a hollowed-out region; the hollowed-out patterns of the first reinforcement layer and the second reinforcement layer may be the same, or the hollowed-out patterns of the first reinforcement layer and the second reinforcement layer may be different, which is not limited in the present disclosure.

(C2) Forming a bending spacer layer. In an exemplary implementation, the forming the bending spacer layer may include: forming a bending spacer layer 35 on a side of the second reinforcement layer 34 away from the display substrate by an attaching process, as shown in FIG. 15, which is a sectional view taken along A-A in FIG. 2.

In an exemplary implementation, the bending spacer layer 35 is provided in the display region, there is no bending spacer layer 35 in the bonding region, and the structure of the bonding region after this process is substantially similar to that after the process of forming the functional hole.

In an exemplary implementation, the bending spacer layer 35 is disposed in a region other than the first functional hole 300. At the position corresponding to the first functional hole 300, the bending spacer layer 35 is formed with a bending spacer hole K6, and the bending spacer hole K6 may be a via structure penetrating through the bending spacer layer 35.

In an exemplary implementation, the position of the bending spacer hole K6 may correspond to the position of the first functional hole 300, the shape of the bending spacer hole K6 may be substantially the same as the shape of the first functional hole 300, and the orthographic projection of the first functional hole 300 on the plane of the display region may be within a range of an orthographic projection of the bending spacer hole K6 on the plane of the display region to ensure that the bending spacer layer 35 may expose the first functional hole 300 after the bending spacer layer 35 is formed.

In an exemplary implementation, an edge of the orthographic projection of the bending spacer hole K6 on the plane of the display region may be located on outside the edge of the orthographic projection of the first functional hole 300 on the plane of the display region in a direction away from the first functional hole 300, and a sixth expansion distance M6 between the edge of the orthographic projection of the bending spacer hole K6 on the plane of the display region and the edge of the orthographic projection of the first functional hole 300 on the plane of the display region may be about 0.2 mm to 0.8 mm, i.e., the bending spacer hole K6 is expanded from 0.2 mm to 0.8 mm relative to the first functional hole 300. For example, taking into account equipment capabilities and alignment tolerances, the sixth expansion distance M6 may be about 0.6 mm.

In an exemplary implementation, the sixth expansion distance M6 may be greater than or equal to the second expansion distance M2.

In an exemplary implementation, the first adhesion layer 31, the first reinforcement layer 32, the second adhesion layer 33, the second reinforcement layer 34 and the bending spacer layer 35 may constitute the reinforcement structural layer of the fixed display region, and the first adhesion hole K2, the first reinforcement hole K3, the second adhesion hole K4, the second reinforcement hole K5 and the bending spacer hole K6 may constitute a first structural hole which is a via structure penetrating through the reinforcement structural layer.

In an exemplary implementation, the second adhesive layer 33, the second reinforcement layer 34 and the bending spacer layer 35 may be provided only in the fixed display region.

In an exemplary implementation, a back film layer may be formed first on a side of the display substrate away from the display structural layer, and then a strengthening structural layer may be formed on a side of the back film layer away from the display structural layer, and the thickness of the back film layer may be about 28 μm to 48 μm. For example, the thickness of the back film layer may be about 38 μm.

In an exemplary implementation, other corresponding film layers may be attached after the formation of the reinforcement structural layer, which is not limited in the present disclosure.

In an exemplary implementation, the strengthening structural layer of the fixed display region may include a first adhesive layer, a first reinforcement layer, a second adhesive layer, a second reinforcement layer, and a bending spacer layer which are stacked, and the strengthening structural layer of the rollable display region may be different from the strengthening structural layer of the fixed display region.

In an exemplary implementation, the strengthening structural layer of the rollable display region may include a first adhesive layer, a first reinforcement layer, a buffer layer, and a back functional layer which are stacked. The structure, material and parameters of the first adhesive layer in the rollable display region may be substantially the same as those of the first adhesive layer in the fixed display region, the structure, material and parameters of the first reinforcement layer in the rollable display region may be substantially the same as those of the first reinforcement layer in the fixed display region, the buffer layer may be disposed on a side of the first reinforcement layer away from the display substrate, and the back functional layer may be disposed on a side of the buffer layer away from the display substrate.

In an exemplary implementation, the first reinforcement layer of the rollable display region may be a patterned structure provided with a hollowed-out region to improve the flexibility of the first reinforcement layer, which is suitable for the rolling of the rollable display region. For example, a plurality of strip grooves may be provided on the first reinforcement layer, each strip groove may extend in the first direction, and the plurality of strip grooves may be sequentially provided in the second direction. As another example, a plurality of block grooves may be arranged on the first reinforcement layer, and the plurality of block grooves are arranged in a matrix mode on the first reinforcement layer to form a grid structure, and the shapes of the block grooves may be any one or more of the following: square, rectangle, pentagon, hexagon, circle and ellipse. For another example, the strip groove or block groove may be a via penetrating through the first reinforcement layer, or may be a blind hole provided on the first reinforcement layer.

In an exemplary implementation, the buffer layer may be made of a FOAM material, and the thickness of the buffer layer may be about 200 μm to 300 μm. For example, the thickness of the buffer layer may be about 250 μm. In an exemplary implementation, by providing a buffer layer in the rollable display region, the buffer layer may play a buffering role, while ensuring the flexibility of the rollable display region, mechanical damage to the rollable display region during the rolling process can be reduced, and the service life of the display panel can be improved.

In an exemplary implementation, the back functional layer may be made of polyethylene terephthalate (PET), and the thickness of the back functional layer may be about 150 μm to 250 μm. For example, the thickness of the back functional layer may be about 214 μm. In an exemplary implementation, by providing a back functional layer in the rollable display region, the back functional layer can play a buffering role, which can further reduce mechanical damage to the rollable display region during the rolling process and improve the service life of the display panel.

(5) Performing a bending process. In an exemplary implementation, performing the bending process may include: flipping the composite circuit region in the bonding region to the back of the display region with the bending region in the bonding region as an axis, so that the bonding substrate 101B of the composite circuit region is attached to the bending spacer layer 35 on the back of the display region, as shown in FIGS. 8 and 9.

In an exemplary implementation, a display panel in an overlapping region between the display region and the bonding region may include a display structural layer 10, a cover plate adhesive layer 41 and a cover plate layer 40 which are stacked on a side (upper side) of the display substrate 101A in an opposite direction of the third direction D3, and a reinforcement structural layer 30, a bonding substrate 101B and a bonding structural layer 20 which are stacked on a side (lower side) of the display substrate 101A in the third direction D3. The reinforcement structural layer 30 may include a first adhesive layer 31, a first reinforcement layer 32, a second adhesive layer 33, a second reinforcement layer 34, and a bending spacer layer 35 which are stacked.

In an exemplary implementation, the cover plate adhesive hole on the cover plate adhesive layer 41 and the first functional hole 300 communicate with each other, the first functional hole 300 and the first structural hole 500 on the reinforcement structural layer 30 communicate with each other, and the first structural hole 500 and the second functional hole 400 communicate with each other, so that the cover plate adhesive hole, the first functional hole 300, the first structural hole 500 and the second functional hole 400 together constitute a camera hole.

In an exemplary implementation, in the bending process, the first functional hole 300 of the display region is aligned with the second functional hole 400 of the bonding region, such that the orthographic projection of the first functional hole 300 on the plane of the display region in the display panel is within a range of the orthographic projection of the second functional hole 400 and the first structural hole 500 on the plane of the display region in the display panel.

In an exemplary implementation, the edge of the orthographic projection of the second functional hole 400 on the plane of the display region is located outside the edge of the orthographic projection of the first functional hole 300 on the plane of the display region in a direction away from the first functional hole 300, and a first distance L1 between the edge of the orthographic projection of the second functional hole 400 on the plane of the display region and the edge of the orthographic projection of the first functional hole 300 on the plane of the display region may be about 0.2 mm to 0.4 mm.

In an exemplary implementation, the edge of the orthographic projection of the first structural hole 500 on the plane of the display region is located on outside the edge of the orthographic projection of the first functional hole 300 on the plane of the display region in a direction away from the first functional hole 300, and a second distance L2 between the edge of the orthographic projection of the first structural hole 500 on the plane of the display region and the edge of the orthographic projection of the first functional hole 300 on the plane of the display region may be about 0.2 mm to 0.8 mm.

In an exemplary implementation, the orthographic projection of the second functional hole 400 on the plane of the display region may be within the range of the orthographic projection of the first structural hole 500 on the plane of the display region.

In an exemplary implementation, the second distance L2 may be greater than or equal to the first distance L1.

In an exemplary implementation, the field of view (FOV) of the camera can be ensured by aligning to make the center line of the first functional hole 300, the center line of the second functional hole 400, and the center line of the first structural hole 500 coincide.

So far, the preparation of the display panel according to an exemplary embodiment of the present disclosure is completed.

As can be seen from the structure and preparation process of the display panel according to an exemplary embodiment of the present disclosure, the exemplary embodiment of the present disclosure provides a scheme for simultaneously opening functional holes on the display region and the bonding region to form a camera hole. In the present disclosure, the fixed display region is arranged on the upper side of the rollable display region, the bonding region is arranged on the upper side of the fixed display region, and the functional hole is arranged on the overlapping region between the display region and the bonding region after being bent, the first functional hole is arranged on the display structural layer of the display region, the first structural hole is arranged on the reinforcement structural layer of the display region, the second functional hole is arranged on the bonding structural layer of the bonding region, and the camera hole is formed on the upper edge of the display device by combining the first functional hole, the second functional hole and the first structural hole, which not only meets user habits and appearance requirements, but also reduces layout difficulty and structural complexity. Compared with the scheme in which functional holes are arranged in the rollable display region, in the present disclosure functional holes are arranged in the fixed display region, thus effectively avoiding the poor display of the rollable display region.

The disclosure can avoid occurrence of crack defects around the functional holes by forming the first functional hole and the second functional hole in a laser punching manner. By providing the orthographic projection of the first functional hole on the plane of the display region within the range of the orthographic projection of the second functional hole on the plane of the display region, the orthographic projection of the first functional hole on the plane of the display region within the range of the orthographic projection of the first structural hole on the plane of the display region, and providing the corresponding expansion for the opening, the present disclosure fully considers equipment capabilities, attachment tolerances, bending tolerances and alignment tolerances, thus ensuring the preparation accuracy of the camera hole and the working performance of the optical device. The preparation method according to the present disclosure does not need to change the existing process flow or process equipment, has little change on the existing process, can be well compatible with the existing preparation process, and has high process realizability and strong practicability.

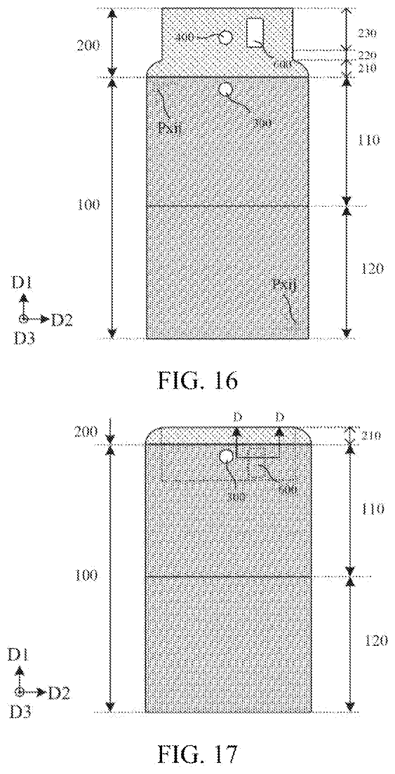

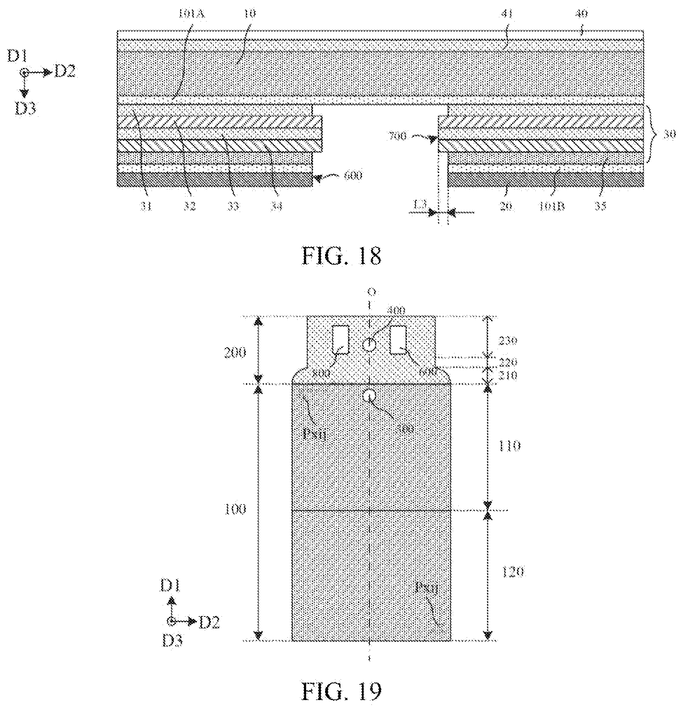

The structure and preparation process of the display panel shown in an exemplary embodiment of the present disclosure are merely illustrative. In practical implementation, a corresponding structure may be changed and patterning processes may be increased or decreased according to actual needs, which is not limited in the present disclosure. FIG. 16 is a schematic diagram of a planar structure of another display panel in an unfolded state according to an exemplary embodiment of the present disclosure, illustrating the unfolded state of the bonding region before bending, FIG. 17 is a schematic diagram of a planar structure of the display panel in FIG. 16 in a bent state, and FIG. 18 a sectional view taken along D-D in FIG. 17. In an exemplary implementation, the main body structure of the display panel of the exemplary embodiment is substantially similar to the structure of the above-mentioned embodiment, except that the bonding region of the exemplary embodiment is further provided with a third functional hole 600, and no functional hole is provided on the display region at the position corresponding to the third functional hole 600.

As shown in FIGS. 16, 17, and 18, on a plane perpendicular to the display region, a display panel in an overlapping region between the display region and the bonding region may include: a display substrate 101A, a display structural layer 10, a cover plate adhesive layer 41 and a cover plate layer 40 which are stacked on an upper surface of the display substrate 101A, a reinforcement structural layer 30, a bonding substrate 101B, and a bonding structural layer which are stacked on the lower surface of the display substrate 101A. A first functional hole 300 having a via structure is provided on the display substrate 101A and the display structural layer 10, and a second functional hole 400 having a via structure and a third functional hole 600 having a via structure are provided on the bonding substrate 101B and the bonding structural layer 20. The structures of the first functional hole 300 and the second functional hole 400 are substantially similar to those of the foregoing embodiments.

In an exemplary implementation, in the second direction D2, a spacing between the second functional hole 400 and the third functional hole 600 may be greater than 2 mm, and the spacing is a distance between an edge of a side of the second functional hole 400 close to the third functional hole 600 and an edge of a side of the third functional hole 600 close to the second functional hole 400.

In an exemplary implementation, the reinforcement structural layer 30 is provided with a second structural hole 700, which may be a via penetrating through the reinforcement structural layer 30, and the third functional hole 600 and the second structural hole 700 communicate so that the third functional hole 600 and the second structural hole 700 are combined into an infrared hole with a via structure, and an infrared device may be provided in the infrared hole. For a near illumination infrared device, the structure of the infrared hole of this embodiment can meet the requirements of the near illumination infrared sensor.

In an exemplary implementation, the position of the second structural hole 700 may correspond to the position of the third functional hole 600, the shape of the second structural hole 700 may be the same as the shape of the third functional hole 600, and an orthographic projection of the second structural hole 700 on the plane of the display region may be within a range of an orthographic projection of the third functional hole 600 on the plane of the display region.

In an exemplary implementation, an edge of the orthographic projection of the third functional hole 600 on the plane of the display region may be located on outside an edge of the orthographic projection of the second structural hole 700 on the plane of the display region in a direction away from the third functional hole 600, and a third distance L3 between the edge of the orthographic projection of the third functional hole 600 on the plane of the display region and the edge of the orthographic projection of the second structural hole 700 on the plane of the display region may be about 0.2 mm to 0.4 mm.

In an exemplary implementation, the reinforcement structural layer 30 may include a first adhesive layer 31, a first reinforcement layer 32, a second adhesive layer 33, a second reinforcement layer 34, and a bending spacer layer 35 which are stacked on a side of the display substrate 101A away from the display structural layer 10. The second structural hole 700 may include a plurality of vias communicated with each other, and the plurality of vias may include a via provided on the first adhesive layer 31, a via provided on the first reinforcement layer 32, a via provided on the second adhesive layer 33, a via provided on the second reinforcement layer 34, and a via provided on the bending spacer layer 35.

In an exemplary implementation, there is no functional hole provided on the display substrate 101A and the display structural layer 10 at positions corresponding to the third functional hole 600 and the second structural hole 700.

In an exemplary implementation, inside walls of the vias provided on the first reinforcement layer 32, the second adhesive layer 33 and the second reinforcement layer 34 may be flush, inside walls of the vias provided on the first adhesive layer 31 and the bending spacer layer 35 may be flush, and the inside wall of the third functional hole 600 and inside walls of vias provided on the bending spacer layer 35 may be flush. In a direction away from the third functional hole 600, the edge of the orthographic projection of the third functional hole 600 on the plane of the display region may be located on outside the edge of the orthographic projection of the via provided on the second reinforcement layer 34 on the plane of the display region, and a third distance L3 between the edge of the orthographic projection of the third functional hole 600 on the plane of the display region and the edge of the orthographic projection of the via provided on the second reinforcement layer 34 on the plane of the display region may be about 0.2 mm to 0.4 mm.

In an exemplary implementation, the preparation process of the display panel of the exemplary embodiment is substantially the same as that of the foregoing embodiments except that: in forming the pattern of the functional hole, the bonding region is further formed with the third functional hole 600; in forming the pattern of the strengthening structural layer of the display panel, corresponding vias are also formed on the first adhesive layer 31, the first reinforcement layer 32, the second adhesive layer 33, the second reinforcement layer 34 and the bending spacer layer 35, and the plurality of vias constitute the second structural hole 700, and the second structural hole 700 is a via structure penetrating through the reinforcement structural layer; in the bending process, the second structural hole 700 and the third functional hole 600 are aligned so that the third functional hole 600 and the second structural hole 700 form an infrared hole.

In an exemplary implementation, in a plane parallel to the display panel, the shape of the third functional hole 600 may be any one or more of the following: rectangular, polygonal, circular and elliptical.

The display panel according to an exemplary embodiment of the present disclosure not only meets user habits and appearance requirements and reduces layout difficulty and structural complexity, but also simplifies a substrate structure and is more conducive to the realization of a full-screen display by providing a third functional hole for an infrared device in the bonding region without digging a hole in the display structural layer of the display region.

FIG. 19 is a schematic diagram of a planar structure of another display panel in an unfolded state of the exemplary embodiment of the present disclosure, illustrating the unfolded state of the bonding region before bending. In an exemplary implementation, the main body structure of the display panel of the exemplary embodiment is substantially similar to the aforementioned structure shown in FIG. 16 except that the bonding region of the exemplary embodiment is also provided with a virtual functional hole 800.

In an exemplary implementation, the virtual functional hole 800 may be a via structure penetrating through the bonding substrate and the bonding structural layer, or the virtual functional hole 800 may be a blind hole structure provided on the bonding structural layer.

In an exemplary implementation, there is no functional hole provided on the display substrate and the display structural layer and no structural hole provided on the reinforcement structural layer in a region corresponding to the virtual functional hole 800.

As shown in FIG. 19, the third functional hole 600 may be provided on a side of the second functional hole 400 in the second direction D2, the virtual functional hole 800 may be provided on a side of the second functional hole 400 in an opposite direction of the second direction D2, the shape of the virtual functional hole 800 may be the same as that of the third functional hole 600, the size of the virtual functional hole 800 may be the same as that of the third functional hole 600, and the third functional hole 600 and the virtual functional hole 800 may be symmetrically provided relative to the second functional hole 400.

In an exemplary implementation, the display panel may have a center line O extending in the first direction D1, which may bisect the display panel in the second direction D2, i.e., the center line O may bisect the display region 100 and the bonding region 200 in the second direction D2. In an exemplary implementation, the orthographic projection of the second functional hole 400 on the plane of the display region at least partially overlaps the orthographic projection of the center line O on the plane of the display region, and the third functional hole 600 and the virtual functional hole 800 may be symmetrically disposed relative to the center line O.

In an exemplary implementation, by arranging the third functional hole 600 and the virtual functional hole 800 to be a symmetrical structure relative to the second functional hole 400 or the center line O, the signal lines in the bonding region are also symmetrically arranged relative to the second functional hole 400 or the center line O, which can ensure the uniformity of the loadings of the signal lines in the bonding region, ensure that the impedances of the signal lines in the bonding region are basically consistent, not only avoid poor color deviation due to the differences in the loadings of the signal lines, improve the display effect, but also avoid the wiring pressure brought due to the centralized distribution of the signal lines on a certain side, simplify the structure of the signal lines in the bonding region, and improve the product yield.

The display panel according to an exemplary embodiment of the present disclosure can not only achieve the technical effect of the structure shown in FIG. 16, but also avoid poor color deviation due to the differences in the loadings of the signal lines and avoid the wiring pressure brought due to the centralized distribution of the signal lines on a certain side by providing the virtual functional hole.

In an exemplary implementation, the display panel of the present disclosure may be applied to a display device with a pixel drive circuit, such as an OLED, a Quantum dot display (QLED), a Light Emitting Diode display (Micro LED or Mini LED), or a Quantum Dot Light Emitting Diode display (QDLED), which is not limited here in the present disclosure.

An exemplary embodiment of the present disclosure further provides a method for preparing a display panel to prepare the display panel of the foregoing exemplary embodiments. In an exemplary implementation, the display panel may include a display region and a bonding region located on a side of the display region in a first direction, the bonding region includes a bending region and a composite circuit region arranged sequentially in a direction away from the display region. The preparation method may include: forming a first functional hole in the display region and forming a second functional hole in the bonding region; and flipping the composite circuit region to a back of the display region by the bending of the bending region, and an orthographic projection of the first functional hole on the plane of the display region at least partially overlaps an orthographic projection of the second functional hole on the plane of the display region.

An exemplary embodiment of the present disclosure also provides a display device, including the foregoing display panel. The display device in the exemplary embodiment of the present disclosure may be any product or component with a display function, such as a mobile phone, a tablet computer, a television, a display, a laptop computer, a digital photo frame, or a navigator.

Although implementations disclosed in the present disclosure are as above, the described contents are only implementations used for convenience of understanding the present disclosure and are not intended to limit the present disclosure. Any person skilled in the art to which the present disclosure pertains may make any modification and variation in implementation forms and details without departing from the spirit and scope disclosed in the present disclosure. However, the scope of patent protection of the present disclosure is still subject to the scope defined by the appended claims.

1. A display panel, comprising a display region, and a bonding region located on a side of the display region in a first direction, wherein the bonding region comprises a bending region and a composite circuit region arranged sequentially in a direction away from the display region, the bending region is configured to flip the composite circuit region to a back of the display region by being bent; the display region is provided with a first functional hole, and the bonding region is provided with a second functional hole, an orthographic projection of the first functional hole on a plane of the display region at least partially overlaps an orthographic projection of the second functional hole on the plane of the display region.

2. The display panel according to claim 1, wherein the orthographic projection of the first functional hole on the plane of the display region is within a range of the orthographic projection of the second functional hole on the plane of the display region.

3. The display panel according to claim 2, wherein an area of the orthographic projection of the first functional hole on the plane of the display region is 70% to 90% of an area of the orthographic projection of the second functional hole on the plane of the display region.

4. The display panel according to claim 2, wherein, in a direction away from the first functional hole, a distance between an edge of the orthographic projection of the first functional hole on the plane of the display region and an edge of the orthographic projection of the second functional hole on the plane of the display region is 0.2 mm to 0.4 mm.

5. The display panel according to claim 1, wherein the display panel has a center line extending along the first direction, the center line bisects the display panel in a second direction, the orthographic projection of the first functional hole on the plane of the display region at least partially overlaps an orthographic projection of the center line on the plane of the display region, the orthographic projection of the second functional hole on the plane of the display region at least partially overlaps the orthographic projection of the center line on the plane of the display region, and the second direction intersects the first direction.

6. The display panel according to claim 1, wherein the display region comprises a fixed display region and a rollable display region connected to each other, the bonding region is located on a side of the fixed display region in the first direction, the rollable display region is located on a side of the fixed display region in an opposite direction of the first direction, the first functional hole is located on the fixed display region, and the second functional hole is located on the composite circuit region in the bonding region.

7. The display panel according to claim 1, wherein, on a plane perpendicular to the display region, a display panel in an overlapping region between the display region and the bonding region comprises: a display substrate, a display structural layer disposed on the display substrate, a reinforcement structural layer disposed on a side of the display substrate away from the display structural layer, a bonding substrate disposed on a side of the reinforcement structural layer away from the display substrate, a bonding structural layer disposed on a side of the bonding substrate away from the display substrate, and the first functional hole is a via penetrating through the display substrate and the display structural layer, the second functional hole is a via penetrating through the bonding substrate and the bonding structural layer, the reinforcement structural layer is provided with a first structural hole penetrating through the reinforcement structural layer, and the first structural hole is communicated with the first functional hole and the second functional hole.

8. The display panel according to claim 7, wherein the reinforcement structural layer comprises: a first adhesive layer disposed on a side of the display substrate away from the display structural layer, a first reinforcement layer disposed on a side of the first adhesive layer away from the display substrate, a second adhesive layer disposed on a side of the first reinforcement layer away from the display substrate, a second reinforcement layer disposed on a side of the second adhesive layer away from the display substrate, and a bending spacer layer disposed on a side of the second reinforcement layer away from the display substrate, wherein the bonding substrate is attached to a side of the bending spacer layer away from the display substrate.

9. The display panel according to claim 8, wherein the first adhesive layer is provided with a first adhesive hole, the orthographic projection of the first functional hole on the plane of the display region is within a range of an orthographic projection of the first adhesive hole on the plane of the display region; in a direction away from the first functional hole, a distance between an edge of the orthographic projection of the first functional hole on the plane of the display region and an edge of the orthographic projection of the first adhesive hole on the plane of the display region is 0.2 mm to 0.8 mm.

10. The display panel according to claim 8, wherein the first reinforcement layer is provided with a first reinforcement hole, and the orthographic projection of the first functional hole on the plane of the display region is within a range of an orthographic projection of the first reinforcement hole on the plane of the display region; in a direction away from the first functional hole, a distance between an edge of the orthographic projection of the first functional hole on the plane of the display region and an edge of the orthographic projection of the first reinforcement hole on the plane of the display region is 0.2 mm to 0.5 mm.

11. The display panel according to claim 8, wherein a distance between an edge of the orthographic projection of the first functional hole on the plane of the display region and an edge of the orthographic projection of the first reinforcement hole on the plane of the display region is greater than a distance between the edge of the orthographic projection of the first functional hole on the plane of the display region and an edge of the orthographic projection of the second functional hole on the plane of the display region.

12. The display panel according to claim 8, wherein a distance between an edge of the orthographic projection of the first functional hole on the plane of the display region and an edge of the orthographic projection of the first adhesive hole on the plane of the display region is greater than a distance between the edge of the orthographic projection of the first functional hole on the plane of the display region and an edge of the orthographic projection of the first reinforcement hole on the plane of the display region.

13. The display panel according to claim 8, wherein the second adhesive layer is provided with a second adhesive hole, and the orthographic projection of the first functional hole on the plane of the display region is within a range of an orthographic projection of the second adhesive hole on the plane of the display region; in a direction away from the first functional hole, a distance between an edge of the orthographic projection of the first functional hole on the plane of the display region and an edge of the orthographic projection of the second adhesive hole on the plane of the display region is 0.2 mm to 0.5 mm.

14. The display panel according to claim 8, wherein the second reinforcement layer is provided with a second reinforcement hole, and the orthographic projection of the first functional hole on the plane of the display region is within a range of an orthographic projection of the second reinforcement hole on the plane of the display region; in a direction away from the first functional hole, a distance between an edge of the orthographic projection of the first functional hole on the plane of the display region and an edge of the orthographic projection of the second reinforcement hole on the plane of the display region is 0.2 mm to 0.5 mm.

15. The display panel according to claim 8, wherein a distance between an edge of the orthographic projection of the first functional hole on the plane of the display region and an edge of the orthographic projection of the first reinforcement hole on the plane of the display region is equal to a distance between the edge of the orthographic projection of the first functional hole on the plane of the display region and an edge of the orthographic projection of the second reinforcement hole on the plane of the display region.

16. The display panel according to claim 8, wherein the bending spacer layer is provided with a bending spacer hole, and the orthographic projection of the first functional hole on the plane of the display region is within a range of an orthographic projection of the bending spacer hole on the plane of the display region; in a direction away from the first functional hole, a distance between an edge of the orthographic projection of the first functional hole on the plane of the display region and an edge of the orthographic projection of the bending spacer hole on the plane of the display region is 0.2 mm to 0.8 mm.

17. The display panel according to claim 7, wherein the bonding region is further provided with a third functional hole, the third functional hole is a via penetrating through the bonding substrate and the bonding structural layer, the reinforcement structural layer is further provided with a second structural hole, the second structural hole is a via penetrating through the reinforcement structural layer, the second structural hole is communicated with the third functional hole, and an orthographic projection of the third functional hole on the plane of the display region at least partially overlaps an orthographic projection of the second structural hole on the plane of the display region.

18. The display panel according to claim 17, wherein the bonding region is further provided with a virtual functional hole, the virtual functional hole has a same shape as the third functional hole, the virtual functional hole has a same size as the third functional hole, and the virtual functional hole and the third functional hole are symmetrically arranged with respect to the second functional hole.

19. A display device, comprising the display panel according to claim 1.

20. A preparation method of a display panel, wherein the display panel comprises a display region, and a bonding region located on a side of the display region, the bonding region comprises a bending region and a composite circuit region arranged sequentially in a direction away from the display region; the preparation method comprises:
forming a first functional hole in the display region and forming a second functional hole in the bonding region;
flipping the composite circuit region to a back of the display region by bending the bending region, wherein an orthographic projection of the first functional hole on the plane of the display region at least partially overlaps an orthographic projection of the second functional hole on the plane of the display region.
